(19) United States
(12) Patent Application Publication
(10) Pub. No.: US 2025/0365960 A1
(43) Pub. Date: Nov. 27, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: KANG LIB KIM, Suwon-si (KR); JAEDUK LEE, Suwon-si (KR); JAEHOON LEE, Suwon-si (KR)

(21) Appl. No.: 19/001,234

(22) Filed: Dec. 24, 2024

(30) Foreign Application Priority Data
May 27, 2024 (KR) 10-2024-0068863

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device may include a gate stack including conductive patterns and insulating patterns, which are alternately stacked on top of each other, a memory channel structure at least partially penetrating the gate stack, a contact structure at least partially enclosed by the gate stack, a penetration structure at least partially enclosed by the gate stack, and a cutting structure including a first cutting pattern at least partially penetrating the contact structure. The conductive patterns may include first, second, and third conductive patterns. The contact structure may include first and second contact plugs, which are in contact with the first and second conductive patterns, respectively, and a spacer enclosing the first and second contact plugs. The cutting structure may be spaced apart from the third conductive pattern, and the first cutting pattern penetrates the spacer and may be between the first and second contact plugs.

### CROSS-REFERENCE TO RELATED APPLICATION

This U.S. non-provisional patent application claims priority under 35 U.S.C. § 119 to Korean Patent Application No. 10-2024-0068863, filed on May 27, 2024, in the Korean Intellectual Property Office, the entire contents of which are hereby incorporated by reference.

### BACKGROUND

The present disclosure relates to a semiconductor device and an electronic system including the same, and in particular, to a semiconductor device including a contact structure and an electronic system including the same.

Due to their small-sized, multifunctional, and/or low-cost characteristics, semiconductor devices are esteemed as important elements in the electronics industry. Semiconductor devices are classified into: semiconductor memory devices for storing data, semiconductor logic devices for processing data, and hybrid semiconductor devices including both memory and logic elements.

With the recent trend of high speed and low power consumption of electronic devices, semiconductor devices in the electronic devices are also required to have high operating speeds and/or low operating voltages. In order to satisfy this requirement, it is necessary to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

An embodiment of the inventive concept provides a semiconductor device with improved electrical characteristics and an electronic system including the same.

According to an embodiment of the inventive concept, a semiconductor device may include a gate stack including conductive patterns and insulating patterns, which are alternately stacked on top of each other, a memory channel structure at least partially penetrating the gate stack, a contact structure at least partially enclosed by the gate stack, a penetration structure at least partially enclosed by the gate stack, and a cutting structure including a first cutting pattern at least partially penetrating the contact structure. The conductive patterns may include a first conductive pattern, a second conductive pattern, and a third conductive pattern, wherein the first conductive pattern and the second conductive pattern are coplanar with each other and the second conductive pattern is not coplanar with the third conductive pattern. The contact structure may include a first contact plug in contact with the first conductive pattern, a second contact plug in contact with the second conductive pattern, and a spacer enclosing the first and second contact plugs. The cutting structure may be spaced apart from the third conductive pattern, and the first cutting pattern at least partially penetrates the spacer and may be disposed between the first and second contact plugs.

According to an embodiment of the inventive concept, a semiconductor device may include a gate stack including conductive patterns and insulating patterns, which are alternately stacked on top of each other, a memory channel structure at least partially penetrating the gate stack, a contact structure at least partially enclosed by the gate stack, a penetration structure at least partially enclosed by the gate stack, and a cutting structure including a cutting pattern at least partially penetrating the contact structure. The conductive patterns may include a first conductive pattern, a second conductive pattern, and a third conductive, wherein the first conductive pattern and the second conductive pattern are coplanar with each other and the second conductive pattern is not coplanar with the third conductive pattern. The contact structure may include a first contact plug in contact with the first conductive pattern, a second contact plug in contact with the second conductive pattern, and a spacer at least partially enclosing the first and second contact plugs. The third conductive pattern may be overlapped with the first conductive pattern, the second conductive pattern, and the cutting pattern in a direction parallel to the direction of penetration of the cutting pattern.

According to an embodiment of the inventive concept, an electronic system may include a main substrate, a semiconductor device on the main substrate, and a controller on the main substrate and electrically connected to the semiconductor device. The semiconductor device may include a gate stack including conductive patterns and insulating patterns, which are alternately stacked on top of each other, a memory channel structure at least partially penetrating the gate stack, a contact structure at least partially enclosed by the gate stack, a penetration structure at least partially enclosed by the gate stack, and a cutting structure including a cutting pattern at least partially penetrating the contact structure. The conductive patterns may include a first conductive pattern, a second conductive, and a third conductive pattern, wherein the first conductive pattern and the second conductive pattern are coplanar with each other and the second conductive pattern is not coplanar with the third conductive pattern. The contact structure may include a first contact plug in contact with the first conductive pattern, a second contact plug in contact with the second conductive pattern, a first spacer overlapped with the first conductive pattern in a direction of penetration of the cutting structure, and a second spacer overlapped with the second conductive pattern in a direction of penetration of the cutting structure. The cutting structure may be spaced apart from the third conductive pattern, each of the first and second spacers may include a contact surface in contact with the cutting pattern, and the contact surface of the first spacer and the contact surface of the second spacer may face each other.

### BRIEF DESCRIPTION OF THE DRAWINGS

FIG. 1A is a schematic diagram illustrating an electronic system including a semiconductor device, according to an embodiment of the inventive concept.

FIG. 1B is a perspective view schematically illustrating an electronic system including a semiconductor device, according to an embodiment of the inventive concept.

FIGS. 1C and 1D are sectional views schematically illustrating a semiconductor package according to an embodiment of the inventive concept.

FIG. 2A is a plan view illustrating a semiconductor device according to an embodiment of the inventive concept.

FIG. 2B is a sectional view taken along a line A-A′ of FIG. 2A.

FIG. 2C is a sectional view taken along a line B-B′ of FIG. 2A.

FIG. 2D is a sectional view taken along a line C-C′ of FIG. 2A.

FIG. 2E is a sectional view taken along a line D-D′ of FIG. 2A.

FIG. 2F is a sectional view taken along a line E-E′ of FIG. 2A.

FIG. 2G is an enlarged plan view illustrating a portion ‘F1’ of FIG. 2A.

FIG. 2H is an enlarged sectional view illustrating a portion ‘F2’ of FIG. 2C.

FIGS. 3A, 3B, 3C, 4A, 4B, 4C, 5A, 5B, 6A, 6B, 6C, 7A, 7B, 8A, 8B, 9A, and 9B are sectional views illustrating a method of fabricating a semiconductor device, according to an embodiment of the inventive concept.

FIG. 10A is a plan view illustrating a semiconductor device according to an embodiment of the inventive concept.

FIG. 10B is a sectional view taken along a line A-A′ of FIG. 10A.

FIG. 10C is a sectional view taken along a line B-B′ of FIG. 10A.

FIGS. 11, 12, 13, 14 and 15 are sectional views illustrating a method of fabricating a semiconductor device, according to an embodiment of the inventive concept.

FIGS. 16A, 16B, 16C, and 16D are sectional views illustrating an semiconductor device according to an embodiment of the inventive concept.

FIGS. 17A, 17B, 17C, and 17D are a sectional view illustrating a semiconductor device according to an embodiment of the inventive concept.

FIG. 18A is a plan view illustrating a semiconductor device according to an embodiment of the inventive concept.

FIG. 18B is an enlarged plan view illustrating a portion ‘G’ of FIG. 18A.

FIG. 19A is a plan view illustrating a semiconductor device according to an embodiment of the inventive concept.

FIG. 19B is an enlarged plan view illustrating a portion ‘H’ of FIG. 19A.

### DETAILED DESCRIPTION

Example embodiments of the inventive concepts will now be described more fully with reference to the accompanying drawings, in which example embodiments are shown.

Hereinafter, example embodiments of the present inventive concept will be described with reference to the accompanying drawings. Hereinafter, the terms such as “top,” “upper portion,” “upper surface,” “above,” “bottom,” “lower portion,” “lower surface,” “below,” and “side surface” may be understood as being referred to based on the drawings except for being denoted by reference numerals. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The terms “penetrating”, “enclosing”, or “filling” as may be used herein may not require completely penetrating or enclosing or filling the described elements or layers, for example, with voids and other discontinuities throughout. Likewise, the term “on” as may be used herein may not require direct contact between the described elements; intervening layers or components may be present.

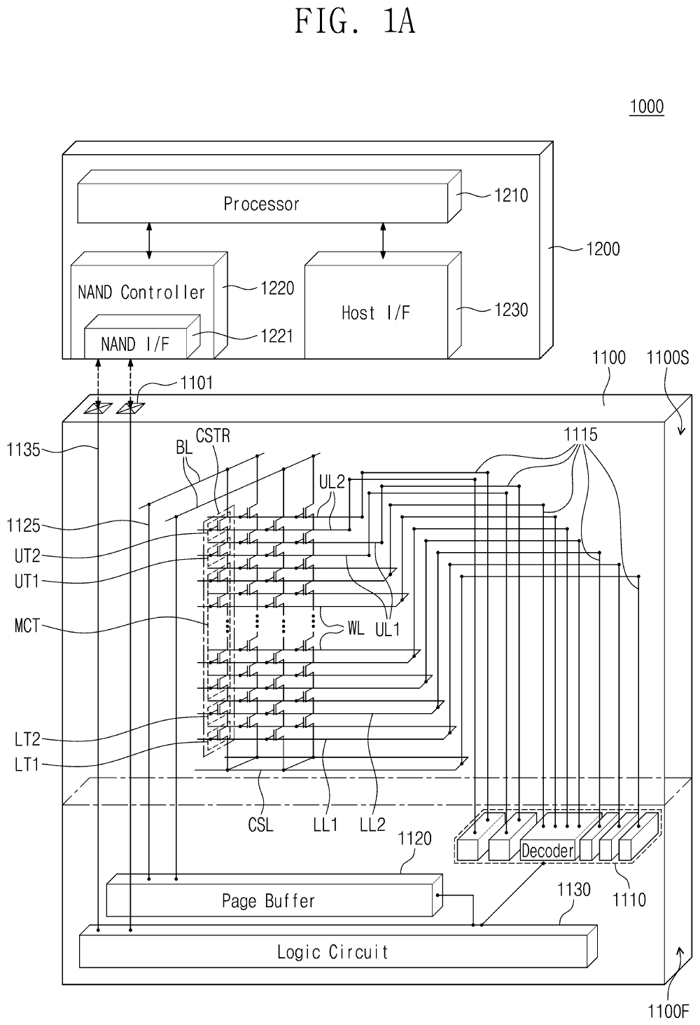

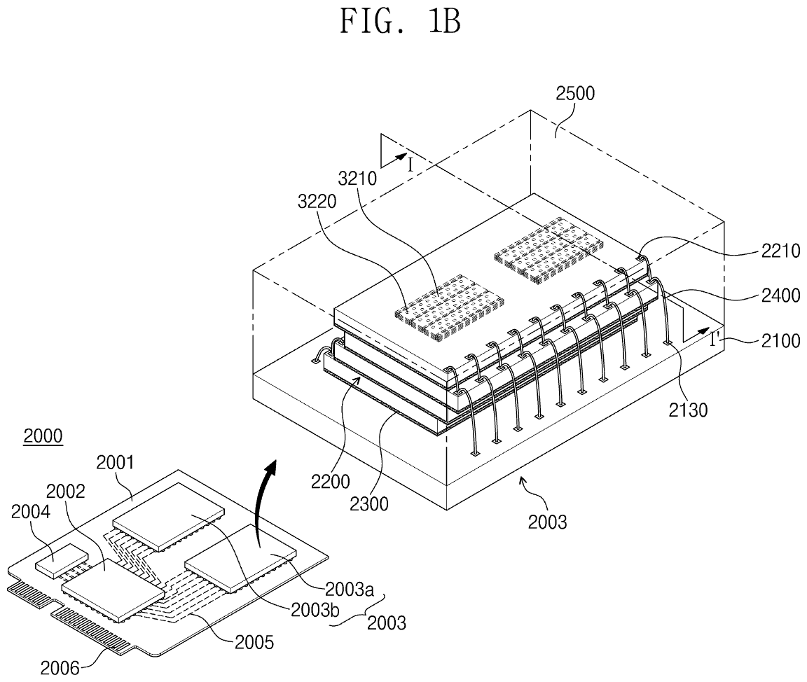

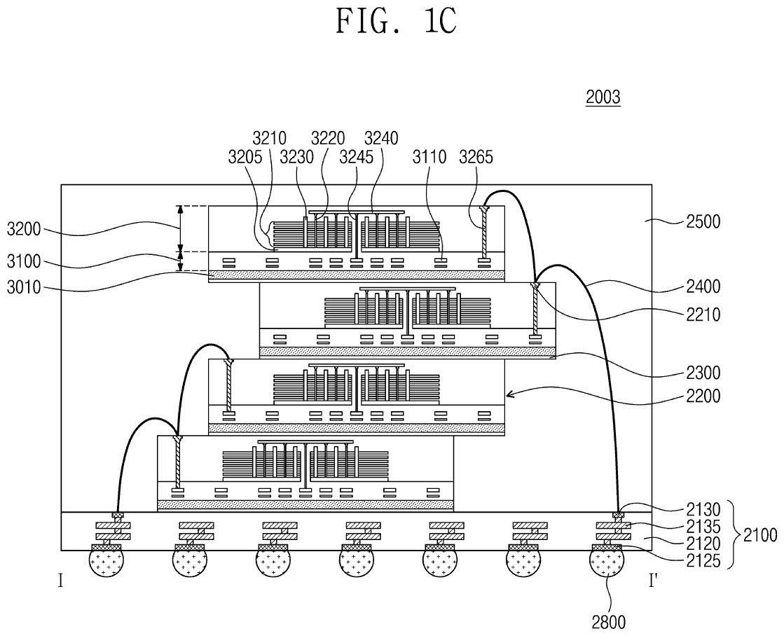

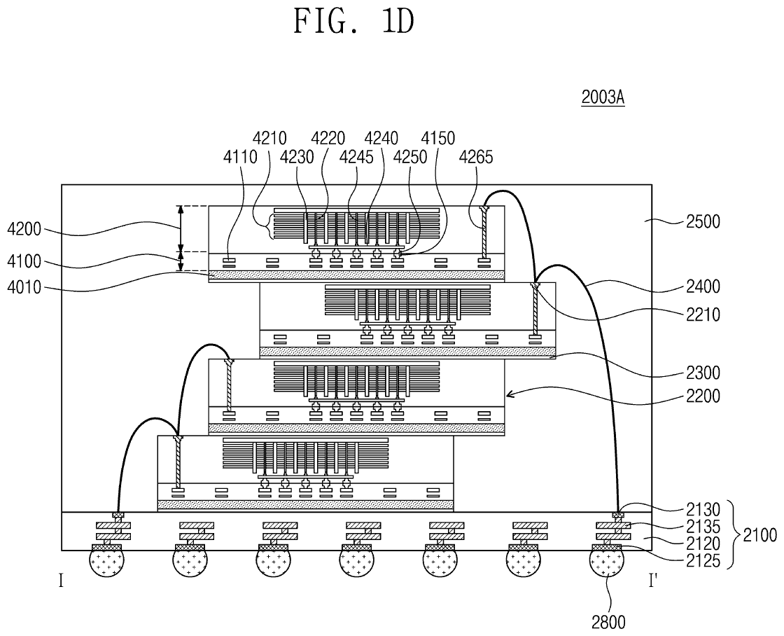

FIG. 1A is a schematic diagram illustrating an electronic system including a semiconductor device according to an embodiment of the inventive concept.

Referring to FIG. 1A, an electronic system 1000 according to an embodiment of the inventive concept may include a semiconductor device 1100 and a controller 1200 electrically connected to the semiconductor device 1100. The electronic system 1000 may be a storage device, which includes one or more semiconductor devices 1100, or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed near the second structure 1100S.

The first structure 1100F may be a peripheral circuit structure, which includes a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be used as gate electrodes of the memory cell transistors MCT, and the gate upper lines UL1 and UL2 may be used as gate electrodes of the upper transistors UT1 and UT2, respectively.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used to perform an erase operation of erasing data in the memory cell transistors MCT using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may be configured to perform a control operation on at least one transistor that is selected from the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135, which is provided in the first structure 1100F and is extended to the second structure 1100S.

Although not shown, the first structure 1100F may include a voltage generator (not shown). The voltage generator may generate a program voltage, a read voltage, a pass voltage, a verification voltage, and so forth, which are needed to operate the memory cell strings CSTR. Here, the program voltage may be a relatively high voltage (e.g., 20V to 40V), compared with the read voltage, the pass voltage, and the verification voltage.

In an embodiment, the first structure 1100F may include high voltage transistors and low voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation). The page buffer 1120 may also include high-voltage transistors which can stand the high voltage.

The controller 1200 may include a processor 1210, a NAND controller 1220, and a host interface 1230. In an embodiment, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands for controlling the semiconductor device 1100 and data to be written in or read from the memory cell transistors MCT of the semiconductor device 1100. The host interface 1230 may be configured to allow for communication between the electronic system 1000 and an external host. If a control command is received from an external host through the host interface 1230, the processor 1210 may control the semiconductor device 1100 in response to the control command.

FIG. 1B is a perspective view schematically illustrating an electronic system including a semiconductor device, according to an embodiment of the inventive concept.

Referring to FIG. 1B, an electronic system 2000 according to an embodiment of the inventive concept may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host, in accordance with one of several interfaces, including, but not limited to universal serial bus (USB), peripheral component interconnect express (PCI-Express), serial advanced technology attachment (SATA), universal flash storage (UFS) M-Phy, or the like. In an embodiment, the electronic system 2000 may be driven by a power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1A. Each of the semiconductor chips 2200 may include stacks 3210 and vertical structures 3220. Each of the semiconductor chips 2200 may include the semiconductor device according to the embodiment described above.

In an embodiment, the connection structure 2400 may include a bonding wire electrically connecting the input/output pad 2210 to the upper pads 2130. That is, in each of the first and second semiconductor packages 2003a and 2003b, the semiconductor chips 2200 may be electrically connected to each other in a bonding wire manner and may be electrically connected to the upper pads 2130 of the package substrate 2100. In an embodiment, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on a separate interposer substrate, which is prepared regardless of the main substrate 2001, and may be connected to each other through interconnection lines, which are provided in the interposer substrate.

FIGS. 1C and 1D are sectional views, which are respectively taken along lines I-I′ and II-II′ of FIG. 1B to illustrate a semiconductor package including a three-dimensional semiconductor memory device according to an embodiment of the inventive concept.

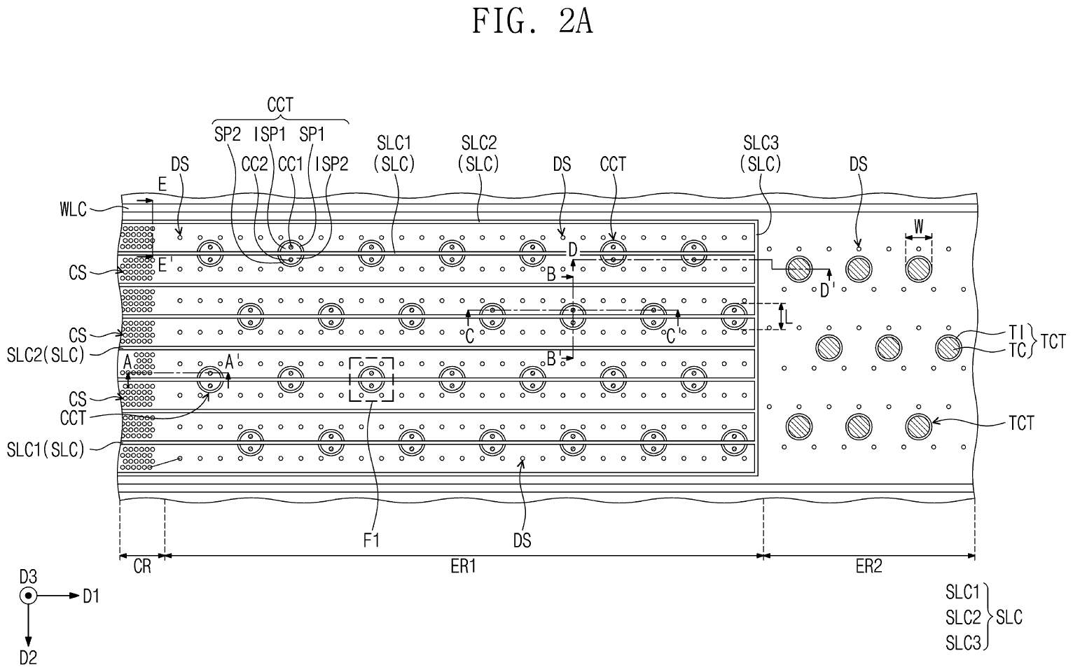

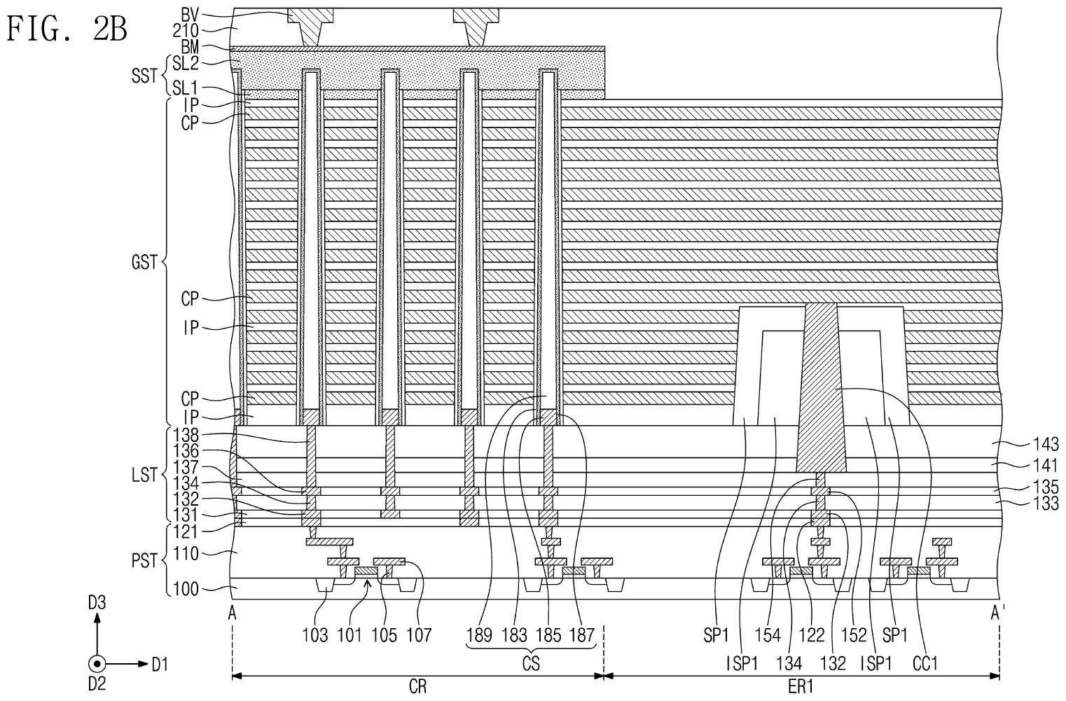

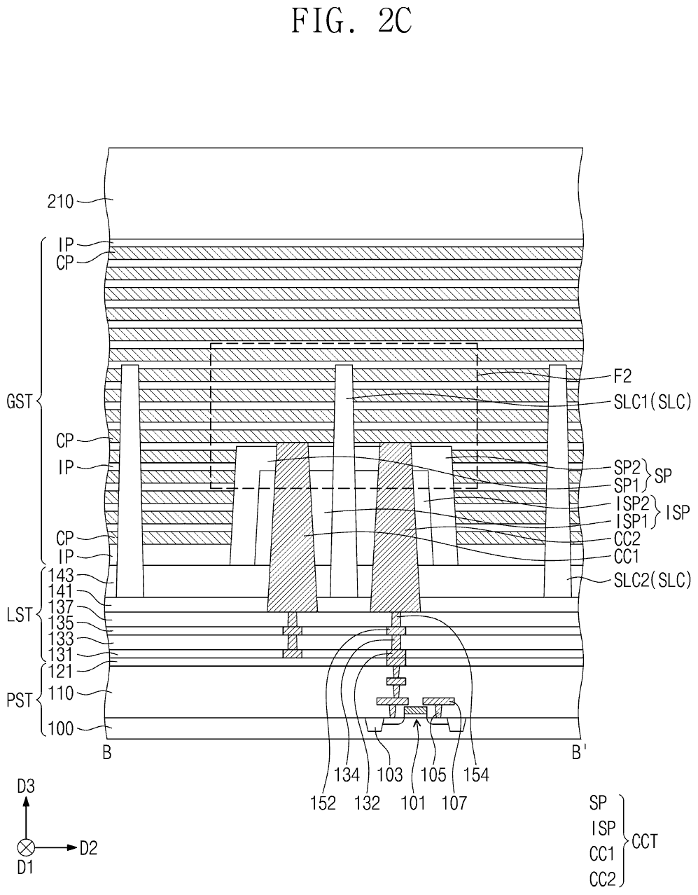

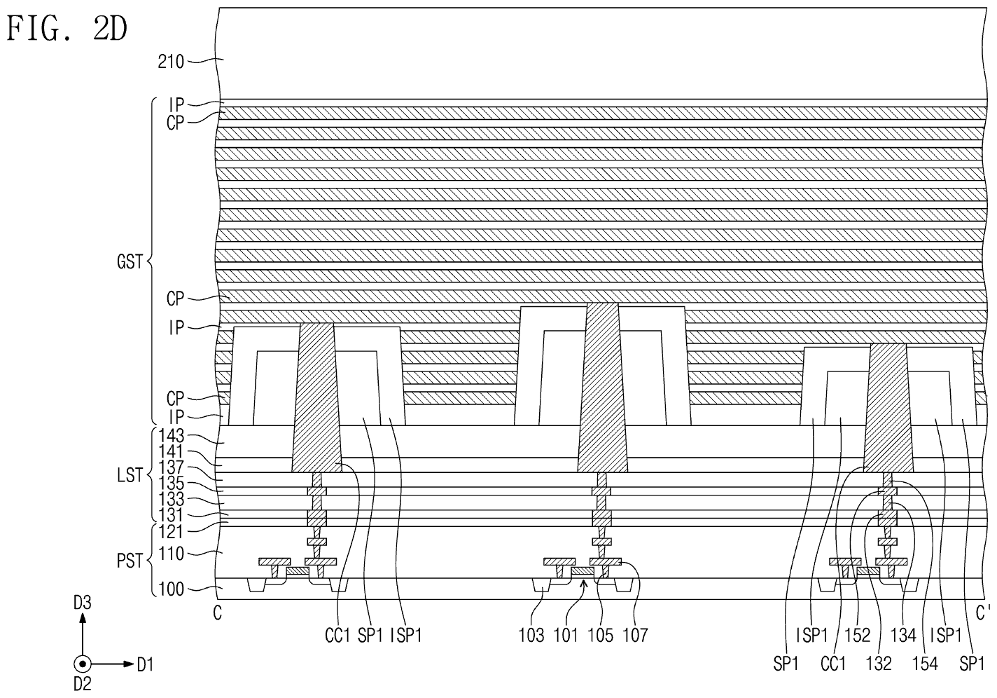

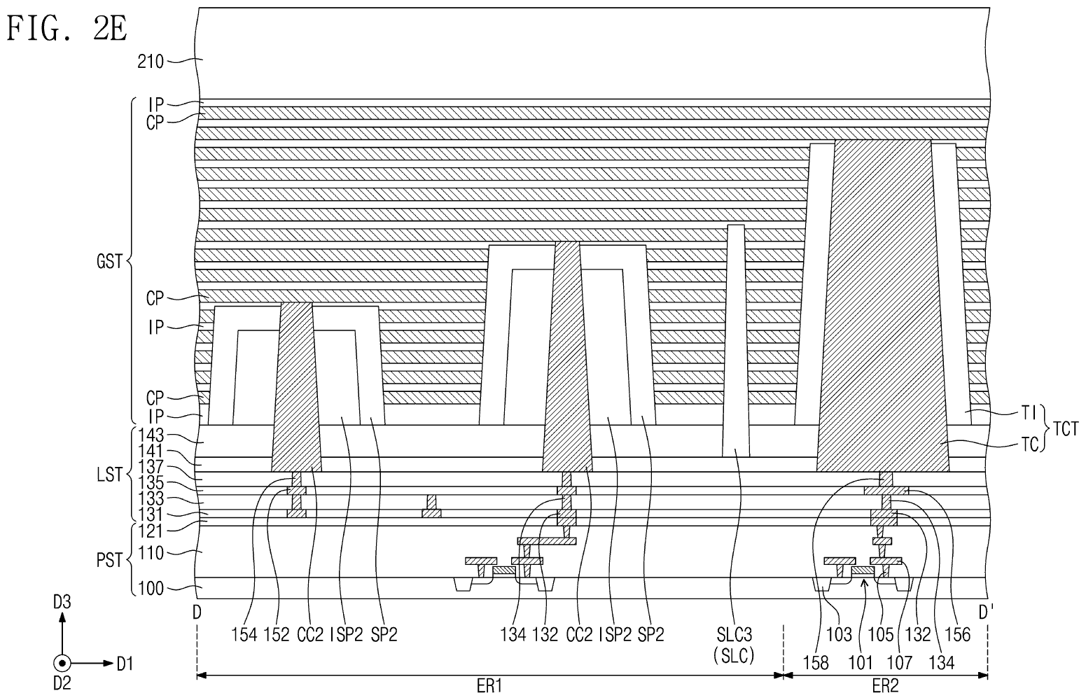

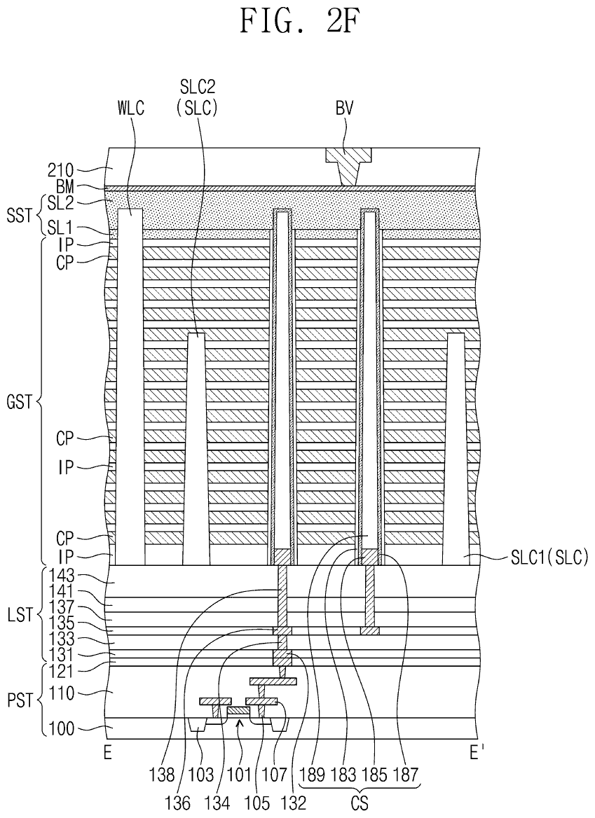

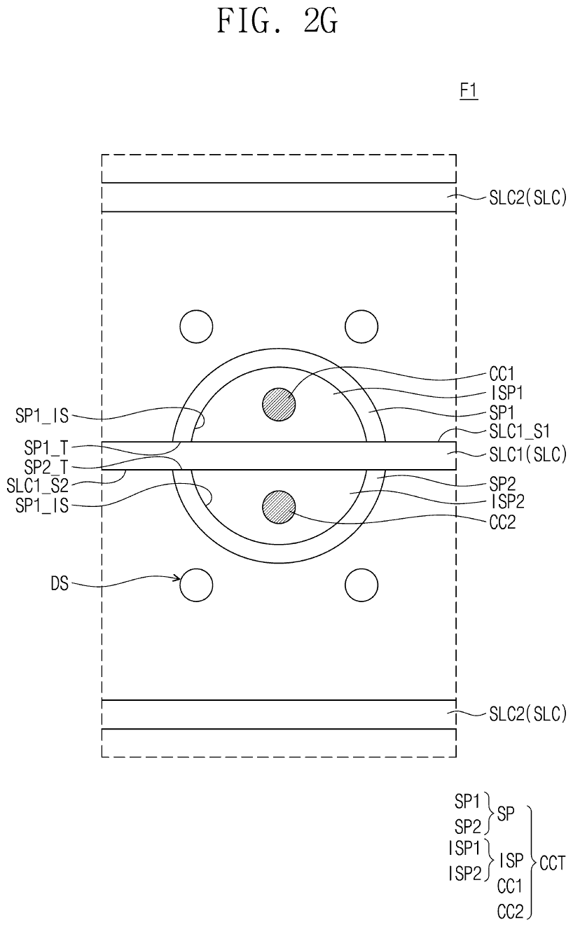

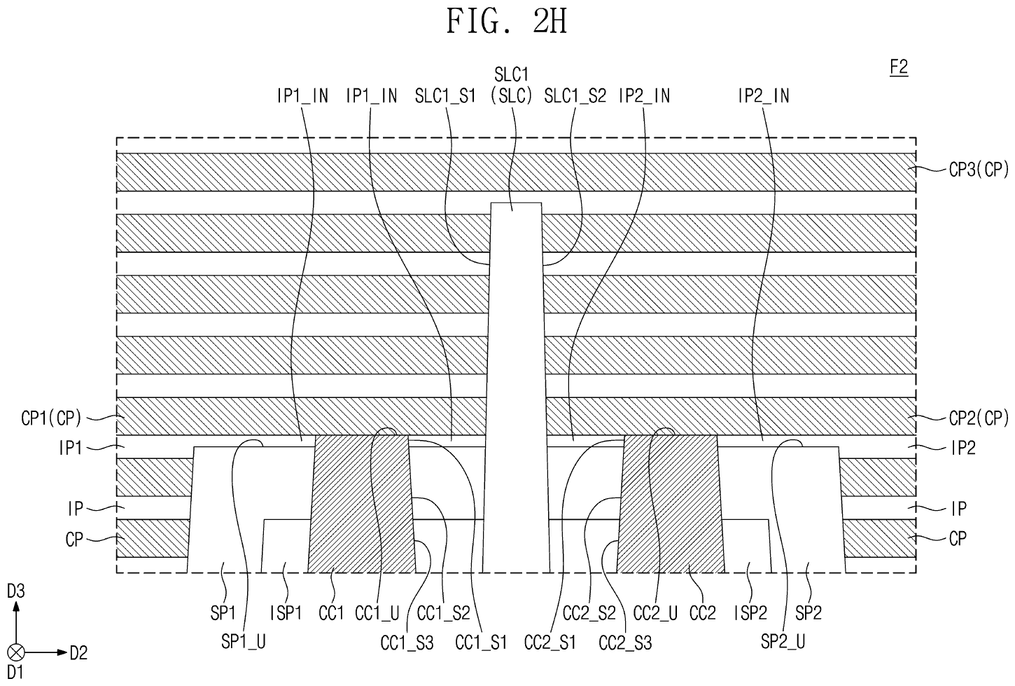

Referring to FIG. 1C, in the semiconductor package 2003, the package substrate 2100 may be a printed circuit board. The package substrate 2100 may include a package substrate body portion 2120, the upper pads 2130 (e.g., of FIG. 1B), which are disposed on a top surface of the package substrate body portion 2120, lower pads 2125, which are disposed on or exposed through a bottom surface of the package substrate body portion 2120, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 of FIG. 2 through conductive connecting portions 2800.

Each of the semiconductor chips 2200 may include a semiconductor substrate 3010 and first and second structures 3100 and 3200, which are sequentially stacked on the semiconductor substrate 3010.

The first structure 3100 of FIG. 1C may correspond to the peripheral circuit structure in the afore-described embodiments, and the second structure 3200 of FIG. 1C may correspond to a cell array structure in the afore-described embodiments.

The first structure 3100 may include a peripheral circuit region, in which peripheral lines 3110 are provided. The second structure 3200 may include a source structure 3205, a stack 3210 on the source structure 3205, the vertical structures 3220 and separation structures penetrating the stack 3210, bit lines 3240 electrically connected to the vertical structures 3220, and cell contact plugs 3230 electrically connected to the word lines WL (e.g., of FIG. 1A) of the stack 3210. Each of the first and second structures 3100 and 3200 and the semiconductor chips 2200 may further include separation structures to be described below.

Each of the semiconductor chips 2200 may include penetration lines 3245, which are electrically connected to the peripheral lines 3110 of the first structure 3100 and are extended into the second structure 3200. The penetration line 3245 may be disposed outside the stack 3210, and in an embodiment, the penetration line 3245 may further penetrate the stack 3210. Each of the semiconductor chips 2200 may further include the input/output pad 2210 (e.g., see FIG. 1B), which is electrically connected to the peripheral lines 3110 of the first structure 3100.

Referring to FIG. 1D, each of the semiconductor chips 2200 in the semiconductor package 2003A may include a semiconductor substrate 4010, a first structure 4100 on the semiconductor substrate 4010, and a second structure 4200, which is provided on and bonded to the first structure 4100 by a wafer bonding process. The first structure 4100 of FIG. 1D may correspond to the peripheral circuit structure in the afore-described embodiments, and the second structure 4200 of FIG. 1D may correspond to the cell array structure in the afore-described embodiments.

The first structure 4100 may include a peripheral circuit region, in which a peripheral line 4110 and first junction structures 4150 are provided. The second structure 4200 may include a source structure 4205, a stack 4210 between the first structure 4100 and the source structure 4205, vertical structures 4220 and a separation structure penetrating the stack 4210, and second junction structures 4250, which are electrically connected to the vertical structures 4220 and the word lines WL (e.g., see FIG. 1A) of the stack 4210. For example, the second junction structures 4250 may be electrically connected to the vertical structures 4220 and the word lines WL (e.g., see FIG. 1A) through bit lines 4240 and cell contact plugs 4230, which are electrically connected to the vertical structures 4220 and the word lines WL (e.g., see FIG. 1A), respectively. The first junction structures 4150 of the first structure 4100 and the second junction structures 4250 of the second structure 4200 may be bonded to each other and may be in contact with each other. The bonded portions of the first and second junction structures 4150 and 4250 may be formed of or include, for example, copper (Cu).

Each of the first and second structures 4100 and 4200 and the semiconductor chips 2200 may further include a source structure according to an embodiment to be described below. Each of the semiconductor chips 2200 may further include the input/output pad 2210 (e.g., see FIG. 1B), which is electrically connected to the peripheral lines 4110 of the first structure 4100.

The semiconductor chips 2200 of FIG. 1C or 1D may be electrically connected to each other by the connection structures 2400, which are provided in the form of bonding wires. However, in an embodiment, semiconductor chips, which are provided in the same semiconductor package as the semiconductor chips 2200 of FIG. 1C or 1D, may be electrically connected to each other by a connection structure including through silicon vias (TSVs).

FIG. 2A is a plan view illustrating a semiconductor device according to an embodiment of the inventive concept. FIG. 2B is a sectional view taken along a line A-A′ of FIG. 2A. FIG. 2C is a sectional view taken along a line B-B′ of FIG. 2A. FIG. 2D is a sectional view taken along a line C-C′ of FIG. 2A. FIG. 2E is a sectional view taken along a line D-D′ of FIG. 2A. FIG. 2F is a sectional view taken along a line E-E′ of FIG. 2A. FIG. 2G is an enlarged plan view illustrating a portion ‘F1’ of FIG. 2A. FIG. 2H is an enlarged sectional view illustrating a portion ‘F2’ of FIG. 2C.

Referring to FIGS. 2A, 2B, 2C, 2D, 2E, 2F, 2G, and 2H, the semiconductor device may include a peripheral circuit structure PST, an interconnection structure LST on the peripheral circuit structure PST, a gate stack GST on the interconnection structure LST, and a source structure SST on the gate stack GST.

The peripheral circuit structure PST may include a substrate 100. The substrate 100 may be a plate-shaped structure that is extended parallel to a plane defined by a first direction D1 and a second direction D2. The first and second directions D1 and D2 may not be parallel to each other. As an example, the first and second directions D1 and D2 may be horizontal directions that are orthogonal to each other. For example, the substrate 100 may be a semiconductor substrate, an insulating substrate, a silicon-on-insulator (SOI) substrate, or a germanium-on-insulator (GOI) substrate. In an embodiment, the semiconductor substrate may include silicon, germanium, silicon-germanium, GaP, or GaAs.

The substrate 100 may include a cell region CR, a first extension region ER1, and a second extension region ER2. The first extension region ER1 may be provided between the cell region CR and the second extension region ER2. The cell region CR, the first extension region ER1, and the second extension region ER2 may be distinct regions from each other, when viewed in a plan view defined by the first and second directions D1 and D2.

The peripheral circuit structure PST may further include a peripheral circuit insulating structure 110 on the substrate 100. The peripheral circuit insulating structure 110 may include an insulating material. In an embodiment, the peripheral circuit insulating structure 110 may have a multi-layered structure including a plurality of insulating layers.

The peripheral circuit structure PST may further include peripheral transistors 101. The peripheral transistors 101 may be provided between the substrate 100 and the peripheral circuit insulating structure 110. In an embodiment, the peripheral transistor 101 may include source/drain regions, a gate electrode, and a gate insulating layer. Device isolation layers 103 may be provided in the substrate 100. The peripheral transistors 101 may be disposed between the device isolation layers 103. The device isolation layer 103 may include an insulating material. In an embodiment, the device isolation layer 103 may have a multi-layered structure including a plurality of insulating layers.

The peripheral circuit structure PST may further include peripheral contacts 105 and peripheral conductive lines 107. The peripheral contacts 105 and the peripheral conductive lines 107 may be electrically connected to the peripheral transistor 101. The peripheral contacts 105 and the peripheral conductive lines 107 may be provided in the peripheral circuit insulating structure 110. The peripheral contacts 105 and the peripheral conductive lines 107 may include a conductive material.

The peripheral circuit structure PST may further include a first bonding insulating layer 121. The first bonding insulating layer 121 may be provided on the peripheral circuit insulating structure 110. The first bonding insulating layer 121 may include an insulating material. In an embodiment, the first bonding insulating layer 121 may have a multi-layered structure including a plurality of insulating layers.

The peripheral circuit structure PST may further include first bonding pads 122. The first bonding pad 122 may be provided on the peripheral contact 105. The first bonding pad 122 may be electrically connected to the peripheral transistor 101 through the peripheral contact 105 and the peripheral conductive line 107. The first bonding pads 122 may be provided in the first bonding insulating layer 121. The first bonding pads 122 may include a conductive material.

The interconnection structure LST may be provided on the first bonding insulating layer 121. The interconnection structure LST may include a second bonding insulating layer 131, second bonding pads 132, a first interlayer insulating layer 133, lower contacts 134, a second interlayer insulating layer 135, bit lines 136, a third interlayer insulating layer 137, bit line contacts 138, first connection pads 152, first connection contacts 154, second connection pads 156, second connection contacts 158, a fourth interlayer insulating layer 141, and a fifth interlayer insulating layer 143.

The second bonding insulating layer 131 may be provided on the first bonding insulating layer 121. The second bonding insulating layer 131 may include an insulating material. In an embodiment, the second bonding insulating layer 131 may include the same insulating material as the first bonding insulating layer 121. In an embodiment, the second bonding insulating layer 131 may have a multi-layered structure including a plurality of insulating layers.

The second bonding pad 132 may be provided on the first bonding pad 122. The second bonding pads 132 may be provided in the second bonding insulating layer 131. The second bonding pads 132 may include a conductive material.

The second bonding insulating layer 131 may be bonded to the first bonding insulating layer 121 through a wafer bonding process. The second bonding pad 132 may be bonded to the first bonding pad 122 through a wafer bonding process.

The first interlayer insulating layer 133 may be provided on the second bonding insulating layer 131. The first interlayer insulating layer 133 may include an insulating material. In an embodiment, the first interlayer insulating layer 133 may have a multi-layered structure including a plurality of insulating layers.

The lower contact 134 may be provided on the second bonding pad 132. The lower contact 134 may be provided in the first interlayer insulating layer 133. The lower contact 134 may include a conductive material.

The second interlayer insulating layer 135 may be provided on the first interlayer insulating layer 133. The second interlayer insulating layer 135 may include an insulating material. In an embodiment, the second interlayer insulating layer 135 may have a multi-layered structure including a plurality of insulating layers.

The bit line 136 may be provided on the lower contact 134. The bit lines 136 may be provided in the second interlayer insulating layer 135. The bit lines 136 may be extended in the first direction D1. The bit lines 136 may be arranged in the second direction D2. The bit lines 136 may include a conductive material.

The first connection pad 152 and the second connection pad 156 may be provided on the lower contact 134. The first connection pad 152 and the second connection pad 156 may be provided in the second interlayer insulating layer 135. The first connection pad 152 and the second connection pad 156 may be extended in the first direction D1. The first connection pads 152 may be arranged in the second direction D2. The second connection pads 156 may be arranged in the second direction D2. The first connection pad 152 and the second connection pad 156 may include a conductive material.

The third interlayer insulating layer 137 may be provided on the second interlayer insulating layer 135. The third interlayer insulating layer 137 may include an insulating material. In an embodiment, the third interlayer insulating layer 137 may have a multi-layered structure including a plurality of insulating layers.

The bit line contact 138 may be provided on the bit line 136. The bit line contacts 138 may be provided in the third interlayer insulating layer 137. The bit line contacts 138 may include a conductive material.

The first connection contact 154 may be provided on the first connection pad 152. The second connection contact 158 may be provided on the second connection pad 156. The first connection contact 154 and the second connection contact 158 may be provided in the third interlayer insulating layer 137. The first connection contact 154 and the second connection contact 158 may include a conductive material.

The first connection pad 152 and the first connection contact 154 may be provided on the first extension region ER1. The second connection pad 156 and the second connection contact 158 may be provided on the second extension region ER2.

The fourth interlayer insulating layer 141 may be provided on the third interlayer insulating layer 137. The fifth interlayer insulating layer 143 may be provided on the fourth interlayer insulating layer 141. The fourth and fifth interlayer insulating layers 141 and 143 may include an insulating material. Each of the fourth and fifth interlayer insulating layers 141 and 143 may have a multi-layered structure including a plurality of insulating layers.

The number of the interlayer insulating layers 133, 135, 137, 141, and 143 may not be limited to that in the illustrated example. In an embodiment, the number of the interlayer insulating layers 133, 135, 137, 141, and 143 may be less than or equal to four or may be greater than or equal to six. In an embodiment, a plurality of conductive structures may be provided to electrically connect the bit line 136 to the second bonding pad 132, instead of the lower contact 134.

The gate stack GST may be provided on the fifth interlayer insulating layer 143. The gate stack GST may include insulating patterns IP and conductive patterns CP, which are alternately stacked on top of each other in a third direction D3. The third direction D3 may not be parallel to the first and second directions D1 and D2. As an example, the third direction D3 may be a vertical direction that is orthogonal to the first and second directions D1 and D2. The insulating patterns IP may include an insulating material. As an example, the insulating patterns IP may be formed of or include at least one of oxide material or low-k dielectric materials, but the inventive concept is not limited to this example. The conductive patterns CP may include a conductive material. As an example, the conductive patterns CP may be formed of or include at least one of doped semiconductor materials, metallic materials, conductive metal nitride materials, or transition metal materials, but the inventive concept is not limited to this example.

Memory channel structures CS may be provided on the cell region CR. The memory channel structures CS may be extended in the third direction D3 to penetrate the gate stack GST. Each of the memory channel structures CS may include an insulating capping layer 189, a channel layer 187 enclosing the insulating capping layer 189, and a memory layer 183 enclosing the channel layer 187. The insulating capping layer 189 and the channel layer 187 may be provided to penetrate the gate stack GST. The insulating capping layer 189, the channel layer 187, and the memory layer 183 may be enclosed by the gate stack GST. The insulating capping layer 189 may include an insulating material. In an embodiment, the insulating capping layer 189 may include an oxide material, but the inventive concept is not limited to this example. The channel layers 187 may include a conductive material. As an example, the channel layer 187 may be formed of or include undoped poly silicon, but the inventive concept is not limited to this example. The memory layer 183 may be configured to store data. The memory layer 183 may include a material, in which electric charges can be trapped.

Each of the memory channel structures CS may further include a bit line pad 185. The bit line pad 185 may be electrically connected to the peripheral transistor 101 through the bit line contact 138, the bit line 136, the lower contact 134, the second bonding pad 132, the first bonding pad 122, the peripheral conductive line 107, and the peripheral contact 105. The bit line pad 185 may include a conductive material. As an example, the bit line pad 185 may be formed of or include poly silicon or metallic materials, but the inventive concept is not limited to this example.

Separation structures WLC may be provided on the cell region CR, the first extension region ER1, and the second extension region ER2. The separation structure WLC may be extended in the first direction D1. The separation structure WLC may be extended in the third direction D3 to penetrate the gate stack GST. The separation structure WLC may include an insulating material. In an embodiment, the separation structure WLC may further include a conductive material enclosed by an insulating material.

The source structure SST may be provided on the cell region CR. The source structure SST may be provided on the gate stack GST and the memory channel structures CS. The source structure SST may include a first source layer SL1 and a second source layer SL2 on the first source layer SL1. The first source layer SL1 may enclose the memory layer 183. The second source layer SL2 may enclose the channel layer 187. The second source layer SL2 may be in contact with the channel layer 187. The first source layer SL1 and the second source layer SL2 may include a conductive material. As an example, the first source layer SL1 and the second source layer SL2 may include a poly silicon.

A barrier layer BM may be provided on the cell region CR. The barrier layer BM may be provided on the second source layer SL2 of the source structure SST. The barrier layer BM may conformally cover the second source layer SL2 of the source structure SST. The barrier layer BM may include a conductive material.

Upper vias BV may be provided on the cell region CR. The upper via BV may be provided on the barrier layer BM. The upper via BV may be in contact with the barrier layer BM. The upper via BV may include a conductive material.

A cover insulating layer 210 may be provided on the cell region CR, the first extension region ER1, and the second extension region ER2. The cover insulating layer 210 may be provided on the barrier layer BM and the gate stack GST. The cover insulating layer 210 may cover a top surface of the barrier layer BM, a side surface of the source structure SST, and a top surface of the gate stack GST. The cover insulating layer 210 may enclose the upper via BV. The cover insulating layer 210 may include an insulating material.

A cutting structure SLC may be provided on the cell region CR and the first extension region ER1. The cutting structure SLC may be disposed between the separation structures WLC, which are adjacent to each other in the second direction D2. The cutting structure SLC may be enclosed by the gate stack GST. The cutting structure SLC may be provided to penetrate a portion of the gate stack GST and the fifth interlayer insulating layer 143.

The cutting structure SLC may include first cutting patterns SLC1, second cutting patterns SLC2, and third cutting patterns SLC3. The first cutting pattern SLC1 and the second cutting pattern SLC2 may be extended in the first direction D1. The third cutting pattern SLC3 may be extended in the second direction D2. The first cutting patterns SLC1 and the second cutting patterns SLC2 may be alternatingly disposed in the second direction D2. The memory channel structure CS may be disposed between the first cutting pattern SLC1 and the second cutting pattern SLC2.

In an embodiment, each of the first, second, and third cutting patterns SLC1, SLC2, and SLC3 may include an empty space (e.g., a void) therein.

Dummy structures DS may be provided on the first extension region ER1 and the second extension region ER2. The dummy structures DS on the first extension region ER1 may be disposed between the first cutting pattern SLC1 and the second cutting pattern SLC2 of the cutting structure SLC. The dummy structures DS may be arranged in the first direction D1 or the second direction D2, when viewed in a plan view.

Contact structures CCT may be provided on the first extension region ER1. The contact structures CCT may be arranged in the first direction D1 or the second direction D2, when viewed in a plan view. The contact structure CCT may be penetrated by the first cutting pattern SLC1 of the cutting structure SLC. Each of the contact structures CCT may include a first contact plug CC1, a second contact plug CC2, an inner pattern ISP, and a spacer SP. The inner pattern ISP and the spacer SP may be penetrated by the first cutting pattern SLC1 of the cutting structure SLC.

The contact structure CCT may be in contact with the first cutting pattern SLC1. The contact structure CCT may be spaced apart from the second cutting pattern SLC2 and the third cutting pattern SLC3. In an embodiment, due to a difference in etch rate between the gate stack GST and the contact structure CCT, the first, second, and third cutting patterns SLC1, SLC2, and SLC3 have different thicknesses from each other. In an embodiment, due to the difference in etch rate between the gate stack GST and the contact structure CCT, the first, second, and third cutting patterns SLC1, SLC2, and SLC3 may have different lengths from each other in the third direction D3.

The first and second contact plugs CC1 and CC2 may be spaced apart from each other in the second direction D2, with the first cutting pattern SLC1 of the cutting structure SLC interposed therebetween. The first and second contact plugs CC1 and CC2 may be spaced apart from the first cutting pattern SLC1 of the cutting structure SLC. Each of the first and second contact plugs CC1 and CC2 may be provided to penetrate the spacer SP, the inner pattern ISP, and the fourth and fifth interlayer insulating layers 141 and 143. Each of the first and second contact plugs CC1 and CC2 may be electrically connected to the peripheral transistor 101 through the first connection contact 154, the first connection pad 152, the lower contact 134, the second bonding pad 132, the first bonding pad 122, the peripheral conductive line 107, and the peripheral contact 105. The first and second contact plugs CC1 and CC2 may include a conductive material.

In an embodiment, each of the first and second contact plugs CC1 and CC2 may include an empty space (e.g., a void) therein.

The spacer SP may include a first spacer SP1 and a second spacer SP2. The first and second spacers SP1 and SP2 may be spaced apart from each other, with the first cutting pattern SLC1 of the cutting structure SLC interposed therebetween. The first and second spacers SP1 and SP2 may be in contact with the first cutting pattern SLC1 of the cutting structure SLC. The first spacer SP1 may be provided to enclose the first contact plug CC1. The first spacer SP1 may be in contact with the first contact plug CC1. The first contact plug CC1 may be provided to penetrate the first spacer SP1. The second spacer SP2 may be provided to enclose the second contact plug CC2. The second spacer SP2 may be in contact with the second contact plug CC2. The second contact plug CC2 may be provided to penetrate the second spacer SP2. The first and second spacers SP1 and SP2 may include an insulating material.

The inner pattern ISP may include a first inner pattern ISP1 and a second inner pattern ISP2. The first and second inner patterns ISP1 and ISP2 may be spaced apart from each other, with the first cutting pattern SLC1 of the cutting structure SLC interposed therebetween. The first and second inner patterns ISP1 and ISP2 may be in contact with the first cutting pattern SLC1 of the cutting structure SLC. The first inner pattern ISP1 may be in contact with the first spacer SP1 and the first contact plug CC1. The second inner pattern ISP2 may be in contact with the second spacer SP2 and the second contact plug CC2. The first inner pattern ISP1 may be disposed between the first spacer SP1 and the first cutting pattern SLC1 of the cutting structure SLC. The second inner pattern ISP2 may be disposed between the second spacer SP2 and the first cutting pattern SLC1 of the cutting structure SLC. The first and second inner patterns ISP1 and ISP2 may include an insulating material.

Penetration structures TCT may be provided on the second extension region ER2. The penetration structures TCT may be arranged in the first direction D1 or the second direction D2, when viewed in a plan view. The penetration structure TCT may be enclosed by the gate stack GST. Each of the penetration structures TCT may include a penetration contact TC and a penetration insulating layer TI.

The penetration contact TC may be provided to penetrate a portion of the gate stack GST and the fourth and fifth interlayer insulating layers 141 and 143. The penetration contact TC may be connected to the conductive pattern CP of the gate stack GST. A length of the penetration contact TC in the third direction D3 may be larger than a length of the first and second contact plugs CC1 and CC2 in the third direction D3. The penetration contact TC may be electrically connected to the peripheral transistor 101 through the second connection contact 158, the second connection pad 156, the lower contact 134, the second bonding pad 132, the first bonding pad 122, the peripheral conductive line 107, and the peripheral contact 105. The penetration contact TC may include a conductive material.

In an embodiment, the penetration contact TC may include an empty space (e.g., void) therein.

The penetration insulating layer TI may be provided to penetrate a portion of the gate stack GST. The penetration insulating layer TI may enclose a side surface of the penetration contact TC. The penetration insulating layer TI may include an insulating material.

A pair of the second cutting patterns SLC2, which are adjacent to each other, may be spaced apart from each other, with the first cutting pattern SLC1 interposed therebetween. The first contact plug CC1 may be disposed between one of the paired second cutting patterns SLC2 and the first cutting pattern SLC1. The second contact plug CC2 may be disposed between the other of the paired second cutting patterns SLC2 and the first cutting pattern SLC1.

The first and second spacers SP1 and SP2 may be formed of or include the same material. The first and second inner patterns ISP1 and ISP2 may be formed of or include the same material. The first and second inner patterns ISP1 and ISP2 may include a material different from the first and second spacers SP1 and SP2. In an embodiment, the first and second inner patterns ISP1 and ISP2 may include a material having an etch selectivity with respect to the first and second spacers SP1 and SP2.

Referring to FIGS. 2G and 2H, the conductive patterns CP may include a first conductive pattern CP1, a second conductive pattern CP2, and a third conductive pattern CP3. The first and second conductive patterns CP1 and CP2 may be disposed at the same level. The first and second conductive patterns CP1 and CP2 may be spaced apart from each other, with the first cutting pattern SLC1 of the cutting structure SLC interposed therebetween. The first and second conductive patterns CP1 and CP2 may be in contact with the first cutting pattern SLC1 of the cutting structure SLC. The first conductive pattern CP1 may be in contact with the first contact plug CC1. The second conductive pattern CP2 may be in contact with the second contact plug CC2. The third conductive pattern CP3 may be disposed at a level higher than the first and second conductive patterns CP1 and CP2 based on the orientation of FIGS. 2G and 2H. The third conductive pattern CP3 may be spaced apart from the cutting structure SLC. The third conductive pattern CP3 may be disposed at a level higher than the cutting structure SLC based on the orientation of FIGS. 2G and 2H.

The first conductive pattern CP1 may be overlapped with the first spacer SP1, the first inner pattern ISP1, and the first contact plug CC1. The second conductive pattern CP2 may be overlapped with the second spacer SP2, the second inner pattern ISP2, and the second contact plug CC2. The third conductive pattern CP3 may be overlapped with the first conductive pattern CP1, the second conductive pattern CP2, the first spacer SP1, the second spacer SP2, the first inner pattern ISP1, the second inner pattern ISP2, the first contact plug CC1, the second contact plug CC2, and the cutting structure SLC.

The insulating patterns IP may include a first insulating pattern IP1 and a second insulating pattern IP2. The first and second insulating patterns IP1 and IP2 may be spaced apart from each other, with the first cutting pattern SLC1 of the cutting structure SLC interposed therebetween. The first insulating pattern IP1 may be in contact with the first contact plug CC1, the first cutting pattern SLC1 of the cutting structure SLC, the first conductive pattern CP1, and the first spacer SP1. The first insulating pattern IP1 may be disposed on a bottom surface of the first conductive pattern CP1. The first insulating pattern IP1 may be penetrated by the first contact plug CC1. The second insulating pattern IP2 may be in contact with the second contact plug CC2, the first cutting pattern SLC1 of the cutting structure SLC, the second conductive pattern CP2, and the second spacer SP2. The second insulating pattern IP2 may be disposed on a bottom surface of the second conductive pattern CP2. The second insulating pattern IP2 may be penetrated by the second contact plug CC2.

Each of the first and second spacers SP1 and SP2 may include a contact surface SP1_T or SP2_T, an inner side surface SP1_IS or SP2_IS, and a top surface SP1_U or SP2_U. The contact surface SP1_T of the first spacer SP1 and the contact surface SP2_T of the second spacer SP2 may be in contact with the first cutting pattern SLC1 of the cutting structure SLC. The contact surface SP1_T of the first spacer SP1 and the contact surface SP2_T of the second spacer SP2 may face each other. The inner side surface SP1_IS of the first spacer SP1 may be in contact with the first inner pattern ISP1. The inner side surface SP2_IS of the second spacer SP2 may be in contact with the second inner pattern ISP2. The contact surface SP1_T of the first spacer SP1 and the contact surface SP2_T of the second spacer SP2 may be flat. The inner side surface SP1_IS of the first spacer SP1 and the inner side surface SP2_IS of the second spacer SP2 may be curved. A top surface of the first spacer SP1 may be in contact with the first insulating pattern IPL. A top surface of the second spacer SP2 may be in contact with the second insulating pattern IP2.

The first cutting pattern SLC1 of the cutting structure SLC may include a first side surface SLC1_S1 and a second side surface SLC1_S2, which are opposite to each other. The first side surface SLC1_S1 of the first cutting pattern SLC1 may be in contact with the contact surface SP1_T of the first spacer SP1 and the first inner pattern ISP1. The second side surface SLC1_S2 of the first cutting pattern SLC1 may be in contact with the contact surface SP2_T of the second spacer SP2 and the second inner pattern ISP2.

The first contact plug CC1 may be disposed between the inner side surface SP1_IS of the first spacer SP1 and the first side surface SLC1_S1 of the first cutting pattern SLC1. The second contact plug CC2 may be disposed between the inner side surface SP2_IS of the second spacer SP2 and the first side surface SLC1_S1 of the first cutting pattern SLC1.

Each of the first and second contact plugs CC1 and CC2 may include a first side surface CC1_S1 or CC2_S1, a second side surface CC1_S2 or CC2_S2, a third side surface CC1_S3 or CC2_S3, and a top surface CC1_U or CC2_U. The first side surface CC1_S1 of the first contact plug CC1 may be in contact with the first insulating pattern IPL. The second side surface CC1_S2 of the first contact plug CC1 may be in contact with the first spacer SP1. The third side surface CC1_S3 of the first contact plug CC1 may be in contact with the first inner pattern ISP1. The top surface CC1_U of the first contact plug CC1 may be in contact with the bottom surface of the first conductive pattern CP1. The first side surface CC2_S1 of the second contact plug CC2 may be in contact with the second insulating pattern IP2. The second side surface CC2_S2 of the second contact plug CC2 may be in contact with the second spacer SP2. The third side surface CC2_S3 of the second contact plug CC2 may be in contact with the second inner pattern ISP2. The top surface CC2_U of the second contact plug CC2 may be in contact with the bottom surface of the second conductive pattern CP2.

A level of a top surface of the penetration contact TC may be higher than a level of the uppermost portion of the cutting structure SLC. A level of the top surface CC1_U of the first contact plug CC1 and a level of the top surface CC2_U of the second contact plug CC2 may be lower than a level of the uppermost portion of the cutting structure SLC based on the orientation of FIGS. 2G and 2H.

Each of the first and second insulating patterns IP1 and IP2 may include an intervening portion IP1_IN or IP2_IN. The intervening portion IP1_IN of the first insulating pattern IP1 may be interposed between the bottom surface of the first conductive pattern CP1 and the top surface SP1_U of the first spacer SP1. The intervening portion IP1_IN of the first insulating pattern IP1 may be penetrated by the first contact plug CC1. The intervening portion IP1_IN of the first insulating pattern IP1 may be in contact with the first side surface SLC1_S1 of the first cutting pattern SLC1. The intervening portion IP2_IN of the second insulating pattern IP2 may be interposed between the bottom surface of the second conductive pattern CP2 and the top surface SP2_U of the second spacer SP2. The intervening portion IP2_IN of the second insulating pattern IP2 may be penetrated by the second contact plug CC2. The intervening portion IP2_IN of the second insulating pattern IP2 may be in contact with the second side surface SLC1_S2 of the first cutting pattern SLC1.

A distance between the first and second contact plugs CC1 and CC2 may reduce as a level with respect to the substrate 100 is lowered.

The largest width W of the penetration insulating layer TI may be equal to the largest distance L between the first and second spacers SP1 and SP2.

In the semiconductor device according to an embodiment of the inventive concept and an electronic system including the same, the cutting pattern SLC1 may be provided to penetrate the contact structure CCT. In this case, an area of the contact structure CCT may be reduced, and this may make it possible to increase an integration density of the semiconductor device and to improve electrical characteristics of the semiconductor device.

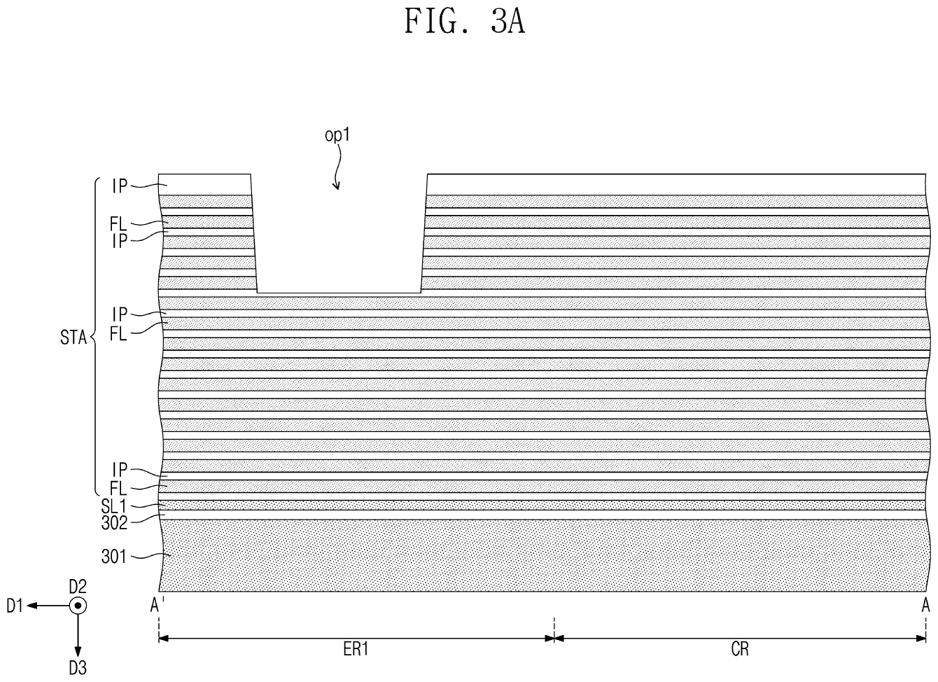

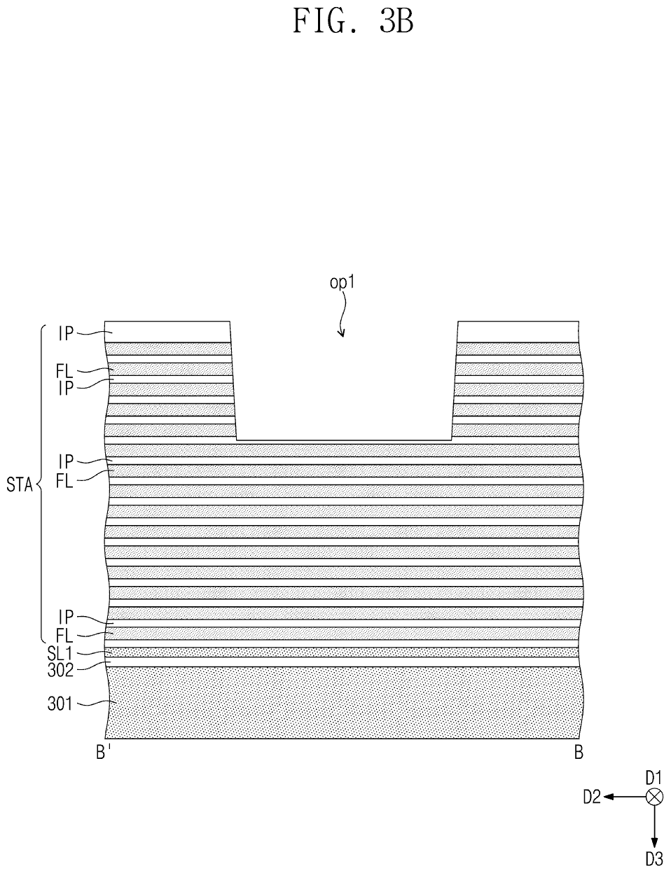

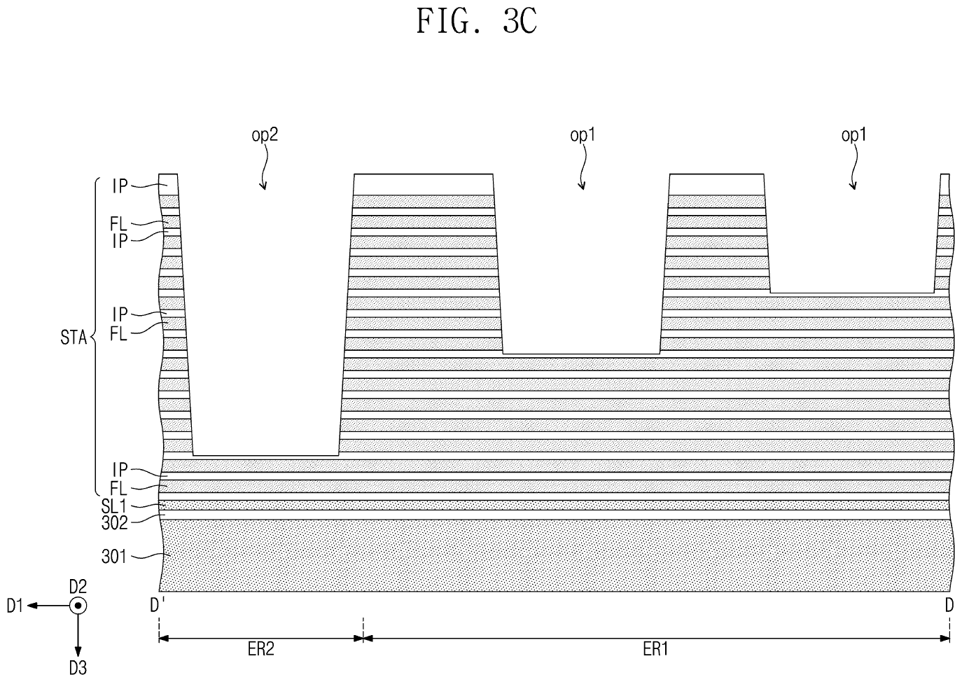

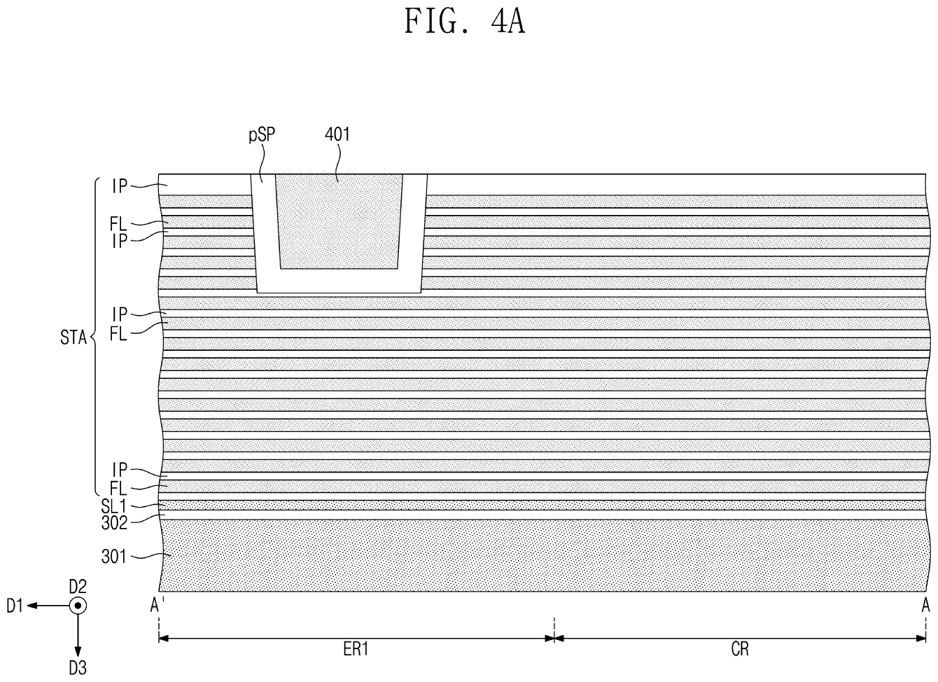

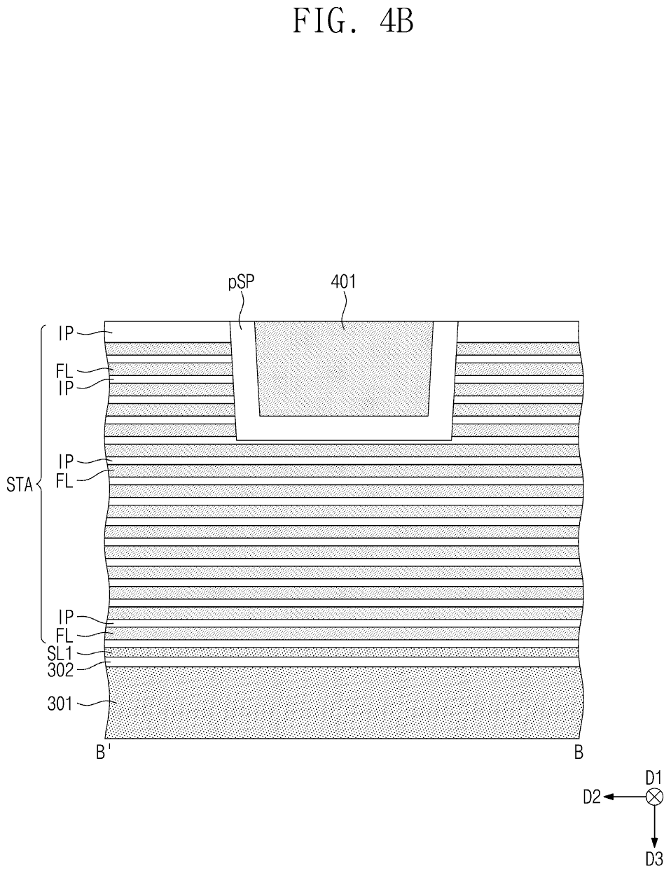

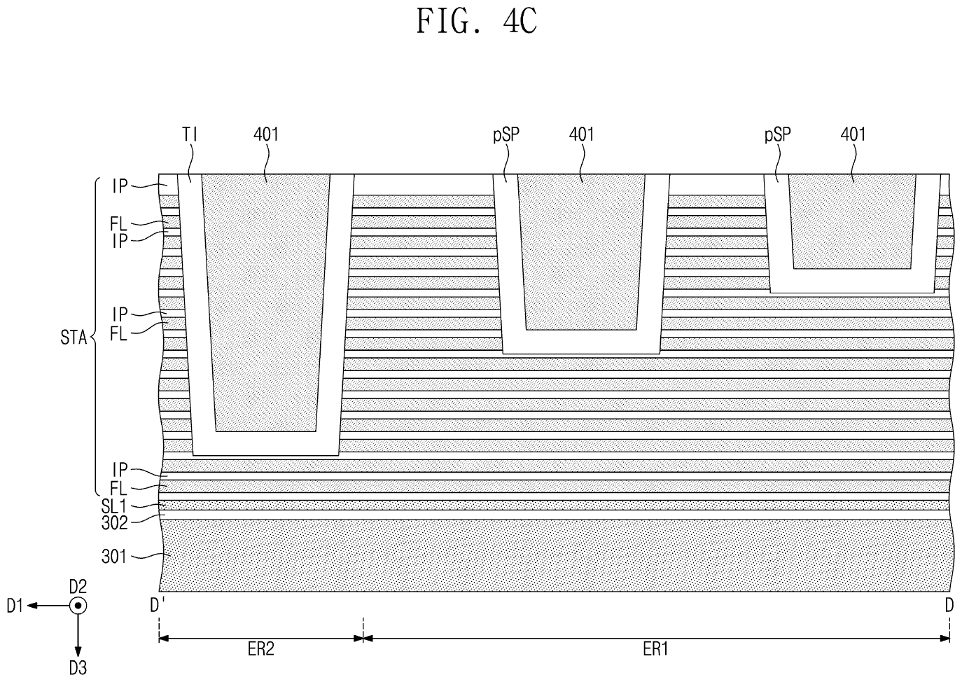

FIGS. 3A, 3B, 3C, 4A, 4B, 4C, 5A, 5B, 6A, 6B, 6C, 7A, 7B, 8A, 8B, 9A, and 9B are sectional views illustrating a method of fabricating a semiconductor device, according to an embodiment of the inventive concept. FIGS. 3A, 4A, 5A, and 6A may correspond to FIG. 2B. FIGS. 3B, 4B, 5B, 6B, 7A, 8A, and 9A may correspond to FIG. 2C. FIGS. 4C, 6C, 7B, 8B, and 9B may correspond to FIG. 2D. FIG. 3C may correspond to FIG. 2E.

Referring to FIGS. 3A, 3B, and 3C, a preliminary substrate 301, a source sacrificial layer 302 on the preliminary substrate 301, the first source layer SL1 on the source sacrificial layer 302, and a stack STA on the first source layer SL1 may be formed.

The stack STA may include the insulating patterns IP and sacrificial layers FL, which are alternately stacked on top of each other. The insulating patterns IP and the sacrificial layers FL may include different insulating materials from each other. In an embodiment, the insulating patterns IP may include an oxide material, and the sacrificial layers FL may include a nitride material.

First holes op1 on the first extension region ER1 and second holes op2 on the second extension region ER2 may be formed. The first hole op1 and the second hole op2 may be formed by removing upper portions of the stack STA. The first hole op1 may be defined by the insulating patterns IP and the sacrificial layers FL, which are exposed on the first extension region ER1 by removing the upper portion of the stack STA. The second hole op2 may be defined by the insulating patterns IP and the sacrificial layers FL, which are exposed on the second extension region ER2 by removing the upper portion of the stack STA. A depth of the second hole op2 may be larger than a depth of the first hole op1.

In an embodiment, the removal of the upper portion of the stack STA may be achieved through an etching process.

Referring to FIGS. 4A, 4B, and 4C, preliminary spacers pSP, penetration insulating layers TI, and contact sacrificial layers 401 may be formed. The preliminary spacer pSP may be formed on the insulating patterns IP and the sacrificial layers FL, which are exposed through the first hole op1 on the first extension region ER1. The preliminary spacer pSP may be formed to conformally cover the insulating patterns IP and the sacrificial layers FL, which are exposed through the first hole op1 on the first extension region ER1. The preliminary spacer pSP may be formed to partially fill the first hole op1. A remaining portion of the first hole op1, which is not filled with the preliminary spacer pSP, may be redefined as the first hole op1. The penetration insulating layer TI may be formed on the insulating patterns IP and the sacrificial layers FL, which are exposed through the second hole op2 on the second extension region ER2. The penetration insulating layer TI may be formed to conformally cover the insulating patterns IP and the sacrificial layers FL, which are exposed through the second hole op2 on the second extension region ER2. The penetration insulating layer TI may be formed to partially fill a portion of the second hole op2. A remaining portion of the second hole op2, which is not filled with the penetration insulating layer TI, may be redefined as the second hole op2. The contact sacrificial layer 401 may be formed on the preliminary spacer pSP or the penetration insulating layer TI. The contact sacrificial layer 401 may fill the first hole op1 or the second hole op2.

The preliminary spacer pSP and the penetration insulating layer TI may include the same material. The contact sacrificial layer 401 may include a material different from the preliminary spacer pSP and the penetration insulating layer TI. As an example, the contact sacrificial layer 401 may include a material having an etch selectivity with respect to the preliminary spacer pSP and the penetration insulating layer TI.

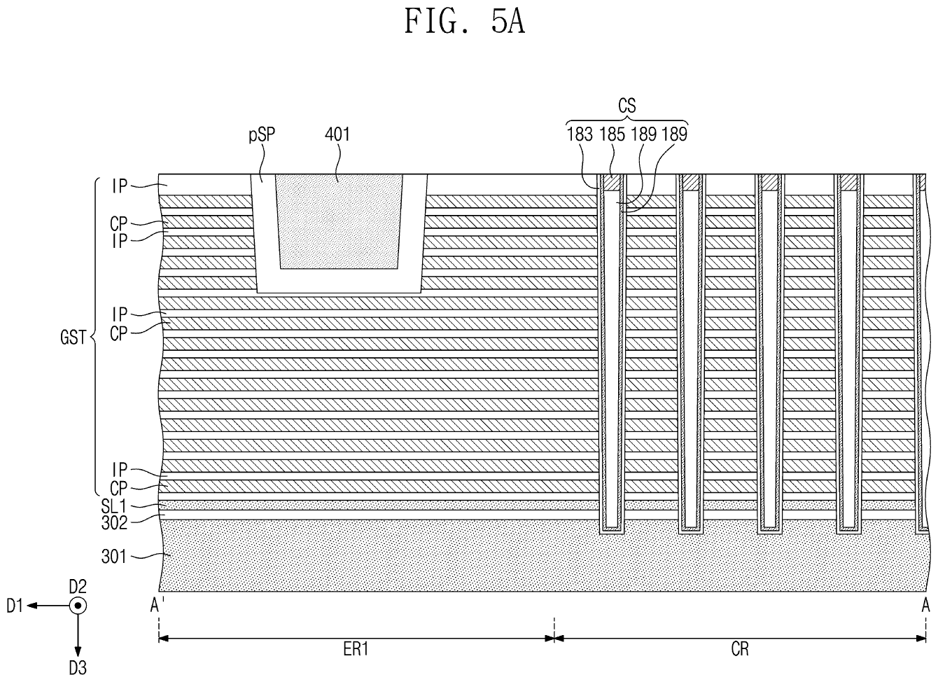

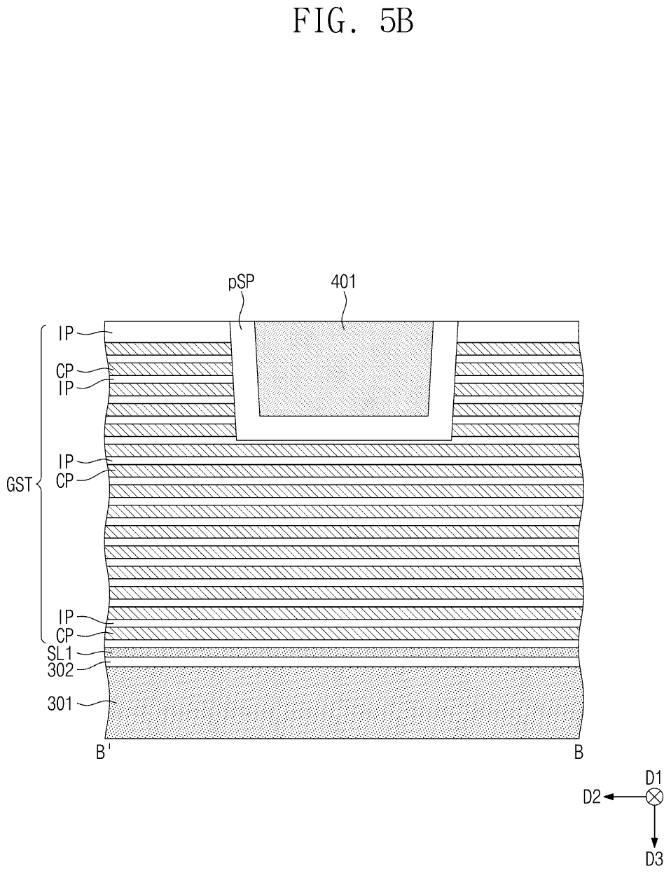

Referring to FIGS. 5A and 5B, the memory channel structures CS and the gate stack GST may be formed. A first opening may be formed by partially removing the insulating patterns IP and the sacrificial layers FL on the cell region CR. The memory channel structure CS may be formed in the first opening.

A second opening may be formed by partially removing the insulating patterns IP and the sacrificial layers FL. The sacrificial layers FL of the stack STA may be exposed through the second opening. The exposed sacrificial layers FL may be removed. The conductive patterns CP may be formed by filling an empty space, which is formed by removing the sacrificial layers FL, with a conductive material. As a result of the formation of the conductive patterns CP, the gate stack GST may be defined. The separation structure WLC may be formed by filling the second opening with an insulating material.

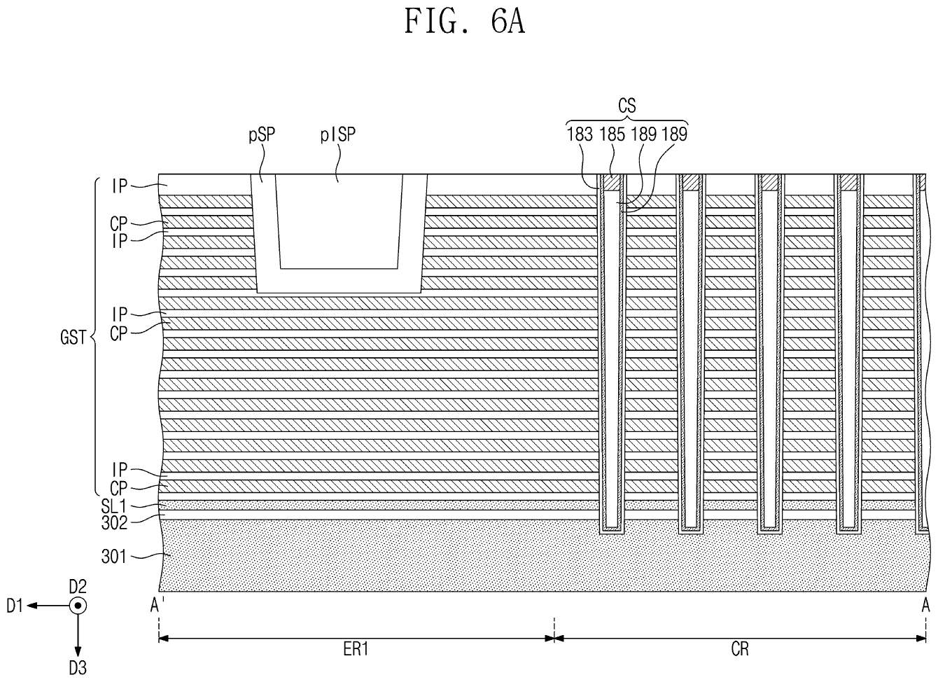

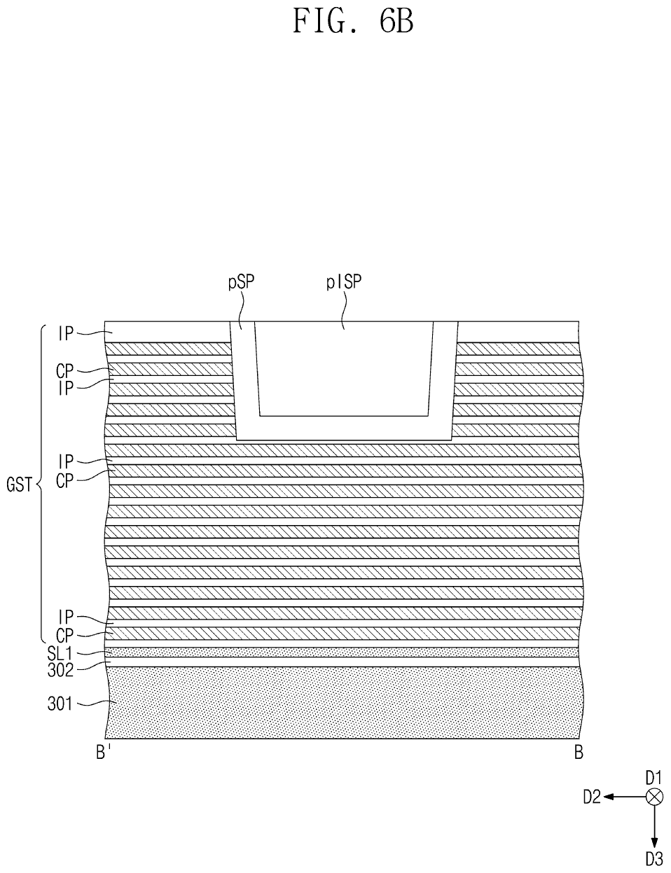

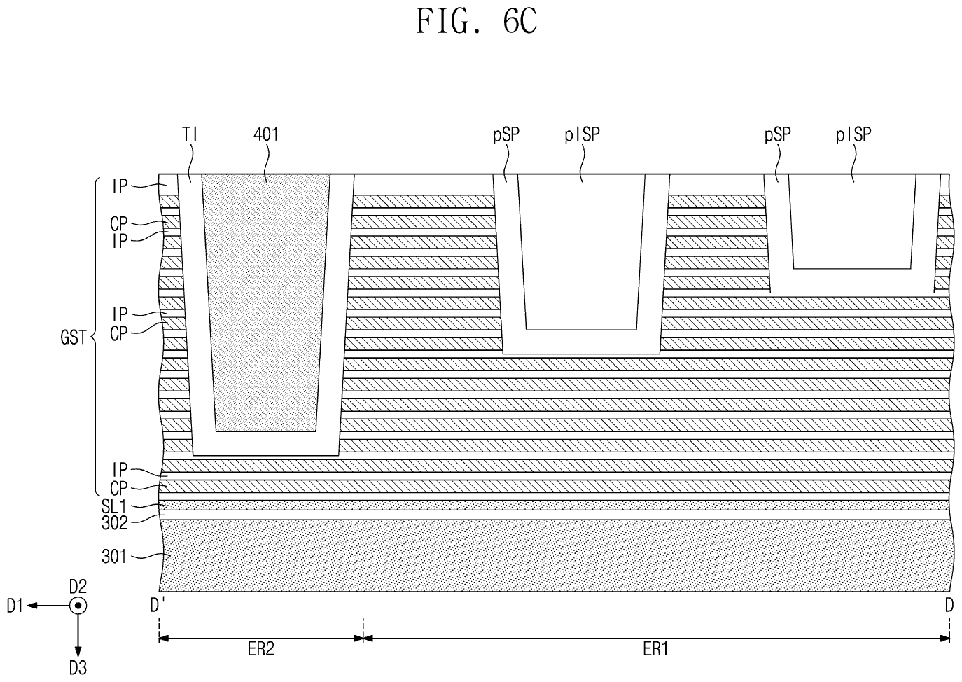

Referring to FIGS. 6A, 6B, and 6C, a preliminary inner pattern pISP may be formed. The contact sacrificial layer 401 on the first extension region ER1 may be removed. Here, the contact sacrificial layer 401 on the second extension region ER2 may or may not be removed. The preliminary inner pattern pISP may be formed by filling an empty space, which is formed by removing the contact sacrificial layer 401 on the first extension region ER1, with an insulating material.

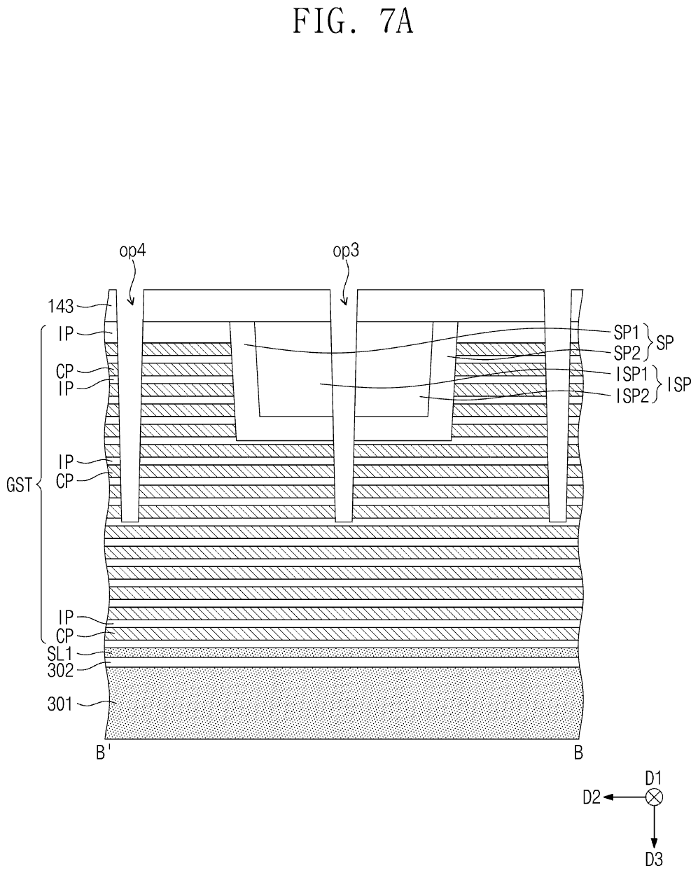

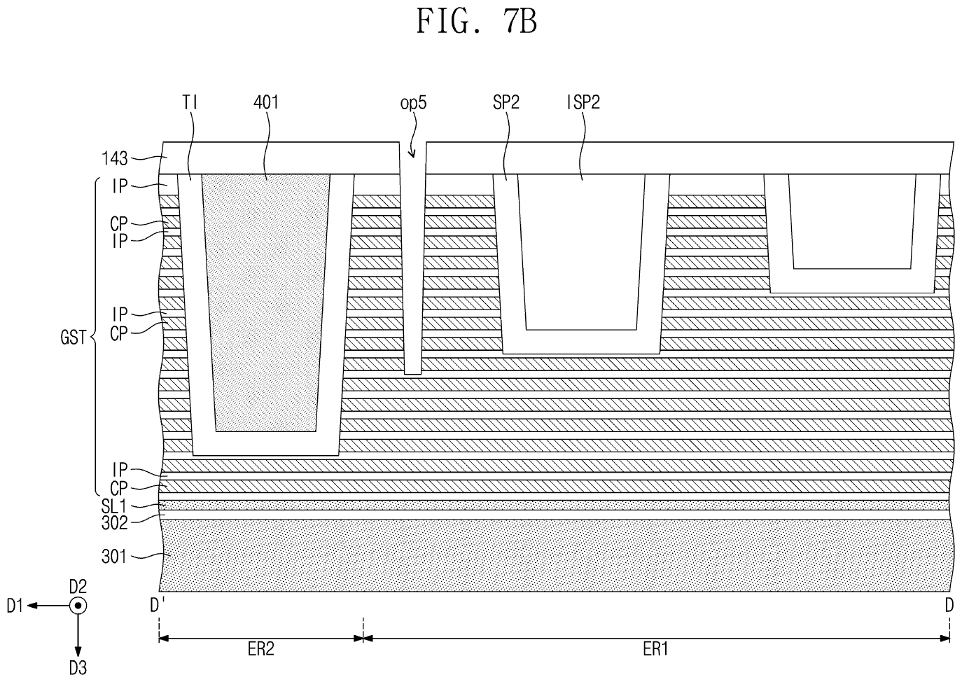

Referring to FIGS. 7A and 7B, the fifth interlayer insulating layer 143 may be formed. The fifth interlayer insulating layer 143 may cover the gate stack GST, the preliminary spacers pSP, and the preliminary inner patterns pISP.

A third hole op3, a fourth hole op4, and a fifth hole op5 may be formed. Each of the conductive patterns CP, the insulating patterns IP, the preliminary spacers pSP, the preliminary inner patterns pISP, and the fifth interlayer insulating layer 143 may be partially removed. An empty space, which is formed by partially removing each of the conductive patterns CP, the insulating patterns IP, the preliminary spacers pSP, the preliminary inner patterns pISP, and the fifth interlayer insulating layer 143 on the first extension region ER1, may be defined as the third hole op3. An empty space, which is formed by partially removing each of the conductive patterns CP, the insulating patterns IP, and the fifth interlayer insulating layer 143 on the first extension region ER1, may be defined as the fourth hole op4. An empty space, which is formed by partially removing each of the conductive patterns CP, the insulating patterns IP, and the fifth interlayer insulating layer 143 on the second extension region ER2, may be defined as the fifth hole op5.

The spacer SP and the inner pattern ISP may be formed as the partial removal of the preliminary spacer pSP and the preliminary inner pattern pISP on the first extension region ER1. Since a portion of the preliminary spacer pSP is removed, the preliminary spacer pSP may be divided into the first and second spacers SP1 and SP2. A remaining portion of the preliminary spacer pSP, which is left after the partial removal, may be defined as the spacer SP. Since a portion of the preliminary inner pattern pISP is removed, the preliminary inner pattern pISP may be divided into the first and second inner patterns ISP1 and ISP2. A remaining portion of the preliminary inner pattern pISP, which is left after the partial removal, may be defined as the inner pattern ISP.

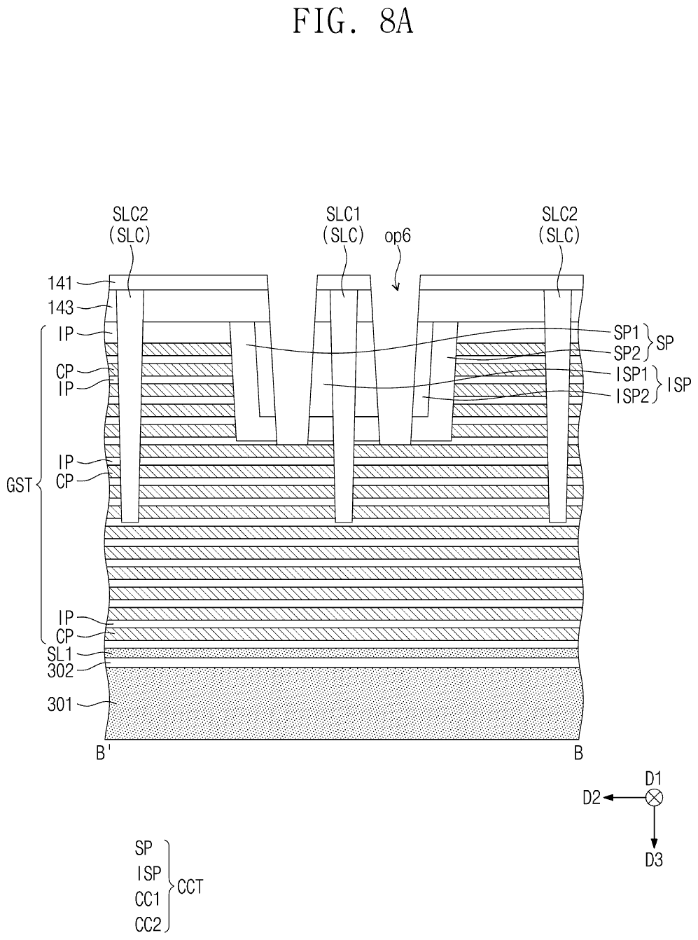

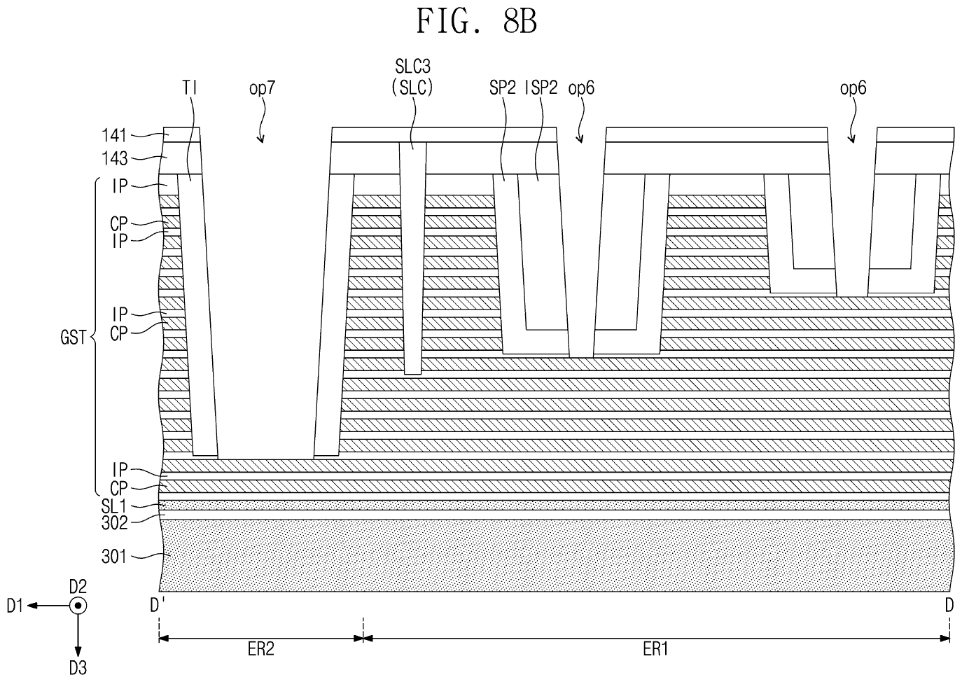

Referring to FIGS. 8A and 8B, the cutting structure SLC may be formed. The cutting structure SLC may be formed by filling the third hole op3, the fourth hole op4, and the fifth hole op5 with an insulating material. The first cutting pattern SLC1 of the cutting structure SLC may be formed by filling the third hole op3 with the insulating material. The second cutting pattern SLC2 of the cutting structure SLC may be formed by filling the fourth hole op4 with the insulating material. The third cutting pattern SLC3 of the cutting structure SLC may be formed by filling the fifth hole op5 with the insulating material.

The fourth interlayer insulating layer 141 may be formed. The fourth interlayer insulating layer 141 may cover the cutting structure SLC and the fifth interlayer insulating layer 143.

A sixth hole op6 and a seventh hole op7 may be formed. The insulating patterns IP, the penetration insulating layer TI, the first spacers SP1, the first inner patterns ISP1, the second spacers SP2, the second inner patterns ISP2, the fourth interlayer insulating layer 141, and the fifth interlayer insulating layer 143 may be partially removed. An empty space, which is formed by partially removing the insulating pattern IP, the first spacer SP1, the first inner pattern ISP1, the second spacer SP2, the second inner pattern ISP2, the fourth interlayer insulating layer 141, and the fifth interlayer insulating layer 143, may be defined as the sixth hole op6. An empty space, which is formed by partially removing the insulating pattern IP, the penetration insulating layer TI, the fourth interlayer insulating layer 141, and the fifth interlayer insulating layer 143, may be defined as the seventh hole op7. The conductive patterns CP of the gate stack GST may be exposed through the sixth hole op6 and the seventh hole op7.

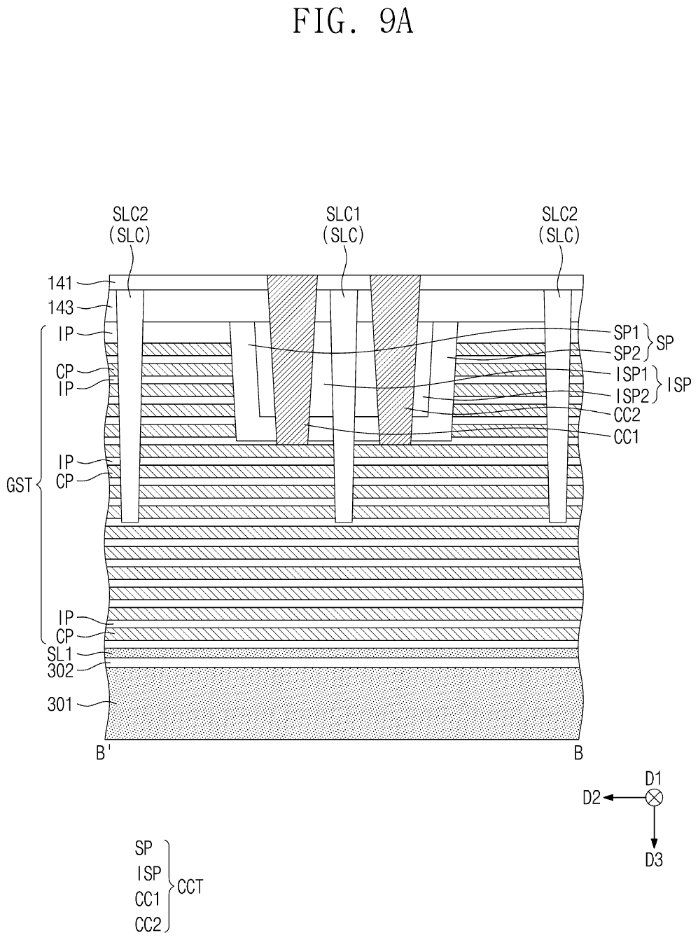

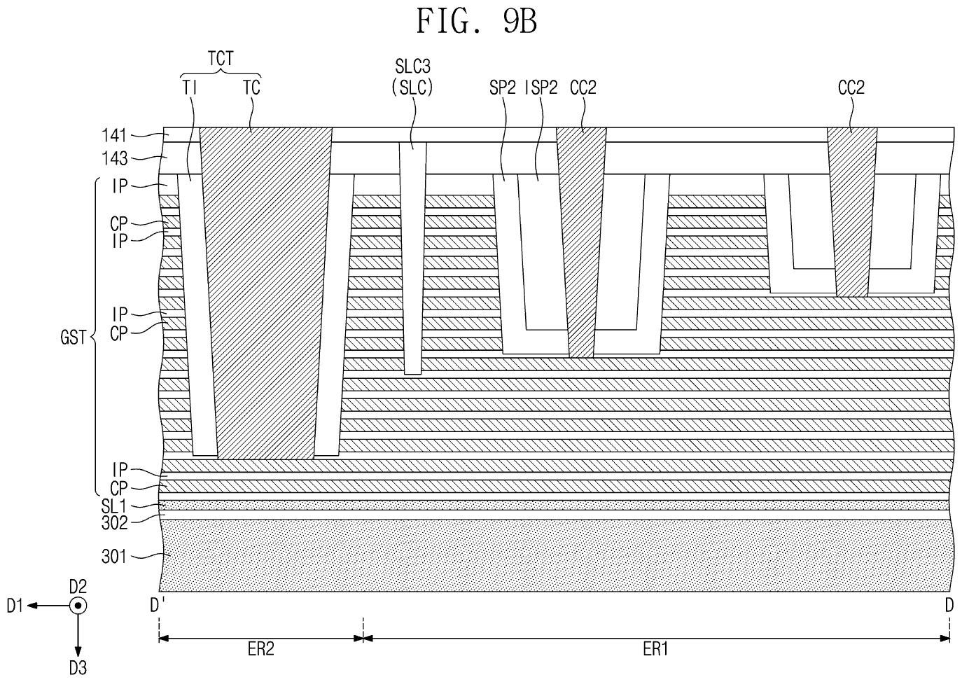

Referring to FIGS. 9A and 9B, the first contact plugs CC1, the second contact plugs CC2, and the penetration contacts TC may be formed. The first contact plug CC1 may be formed by filling the fifth hole op5 with a conductive material. The second contact plug CC2 may be formed by filling the sixth hole op6 with a conductive material. As a result of the formation of the first and second contact plugs CC1 and CC2, the contact structure CCT may be defined. The penetration contact TC may be formed by filling the seventh hole op7 with a conductive material. As a result of the formation of the penetration contact TC, the penetration structure TCT may be formed.

Referring back to FIGS. 2A to 2H, the interconnection structure LST may be formed on the fourth interlayer insulating layer 141, the memory channel structures CS, the contact structures CCT, and the penetration structures TCT. The peripheral circuit structure PST may be prepared. The semiconductor device may be inverted. The inverted semiconductor device may be bonded to the peripheral circuit structure PST prepared. The interconnection structure LST and the peripheral circuit structure PST may be bonded to each other by a wafer bonding process.

The preliminary substrate 301 and the source sacrificial layer 302 may be removed. The second source layer SL2 may be formed on the first source layer SL1 and the memory channel structures CS. The source structure SST may be defined as a result of the formation of the second source layer SL2. The cover insulating layer 210 may be formed on the source structure SST and the gate stack GST. The upper vias BV may be formed on the source structure SST.

In a method of fabricating of a semiconductor device and an electronic system including the same according to an embodiment of the inventive concept, the spacer SP and the penetration insulating layer TI may be formed at the same time. Thus, the fabrication process of the semiconductor device may be simplified.

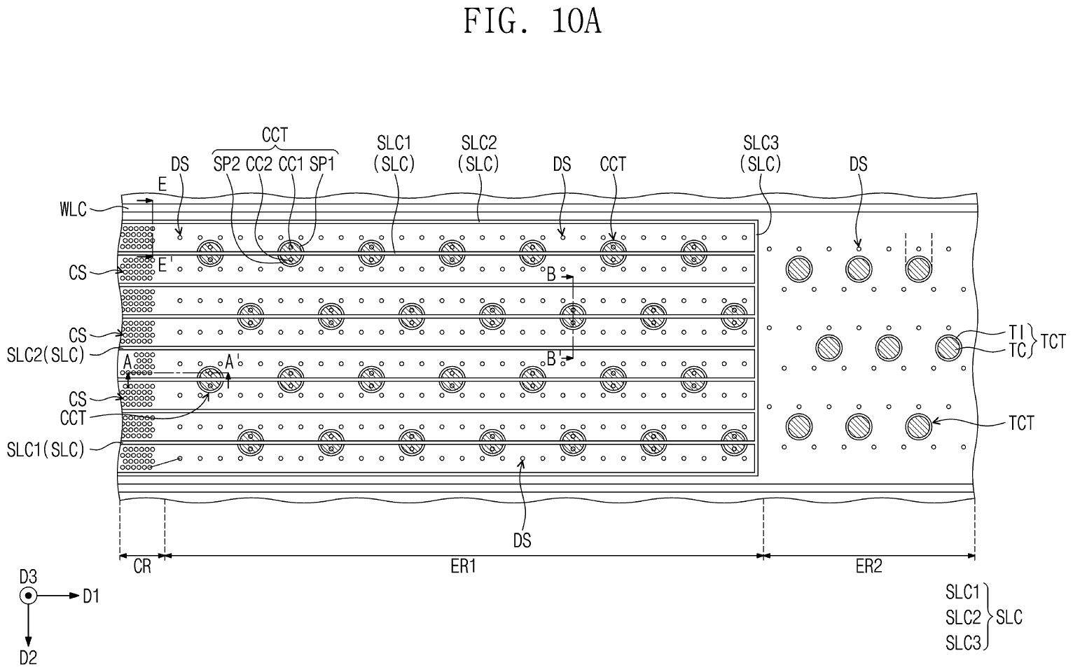

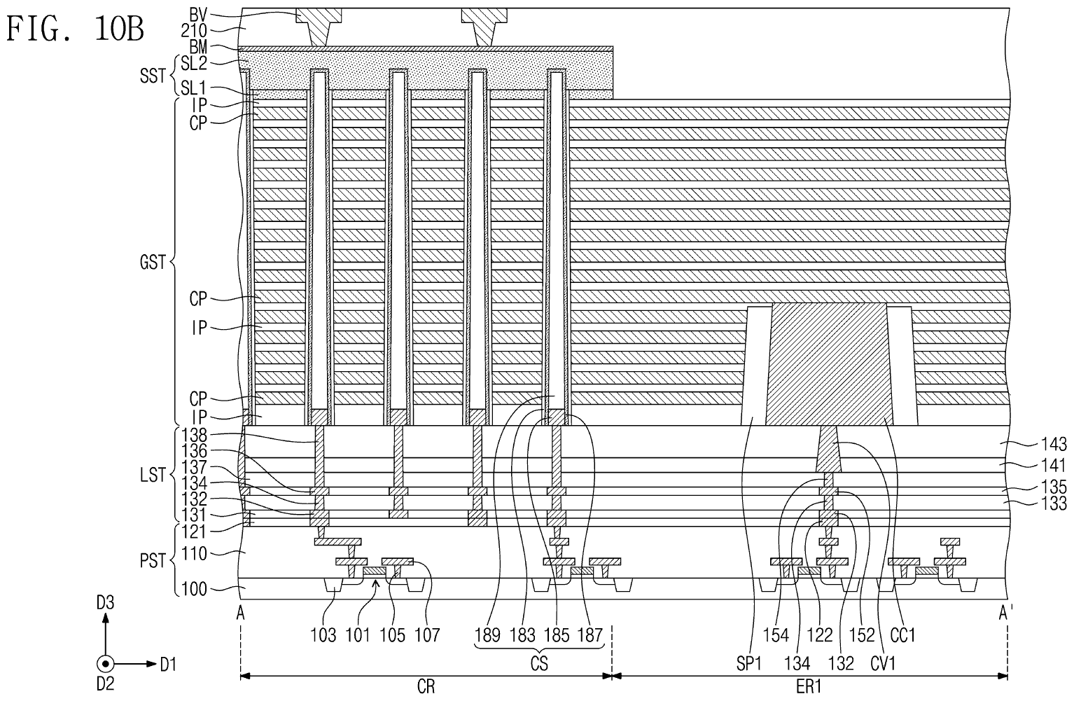

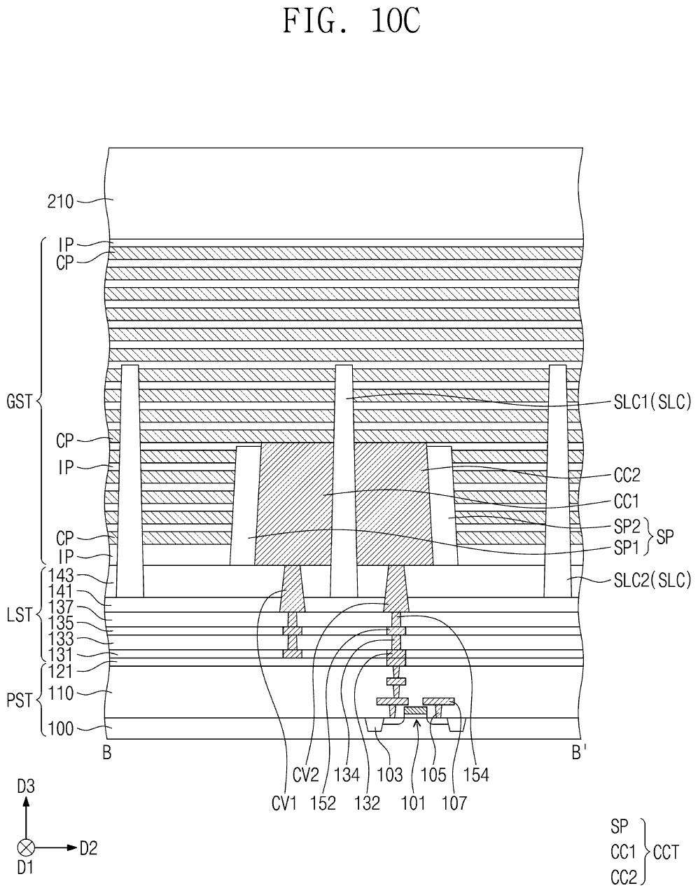

FIG. 10A is a plan view illustrating a semiconductor device according to an embodiment of the inventive concept. FIG. 10B is a sectional view taken along a line A-A′ of FIG. 10A. FIG. 10C is a sectional view taken along a line B-B′ of FIG. 10A. FIG. 10A may correspond to FIG. 2A. FIG. 10B may correspond to FIG. 2B. FIG. 10C may correspond to FIG. 2C. Except for technical features to be described below, the semiconductor device of FIGS. 10A to 10C may be similar to the semiconductor device of FIGS. 2A to 2H.

Referring to FIGS. 10A to 10C, the semiconductor device may or may not include the inner pattern ISP. The first and second contact plugs CC1 and CC2 may be in contact with the first cutting pattern SLC1 of the cutting structure SLC. A level of a bottom surface of the first contact plug CC1 and a bottom surface of the second contact plug CC2 may be higher than a level of a bottom surface of the cutting structure SLC according to the orientation of FIGS. 10A to 10C. The level of the bottom surface of the first contact plug CC1 may be equal to a level of a bottom surface of the first spacer SP1. The level of the bottom surface of the second contact plug CC2 may be equal to a level of a bottom surface of the second spacer SP2.

The semiconductor device may further include first contact vias CV1 and second contact vias CV2. The first and second contact vias CV1 and CV2 may be provided to penetrate the fourth and fifth interlayer insulating layers 141 and 143. The first contact via CV1 may be in contact with the bottom surface of the first contact plug CC1. The first contact via CV1 may electrically connect the first contact plug CC1 to the first connection contact 154. The second contact via CV2 may be in contact with the bottom surface of the second contact plug CC2. The second contact via CV2 may electrically connect the second contact plug CC2 to the first connection contact 154.

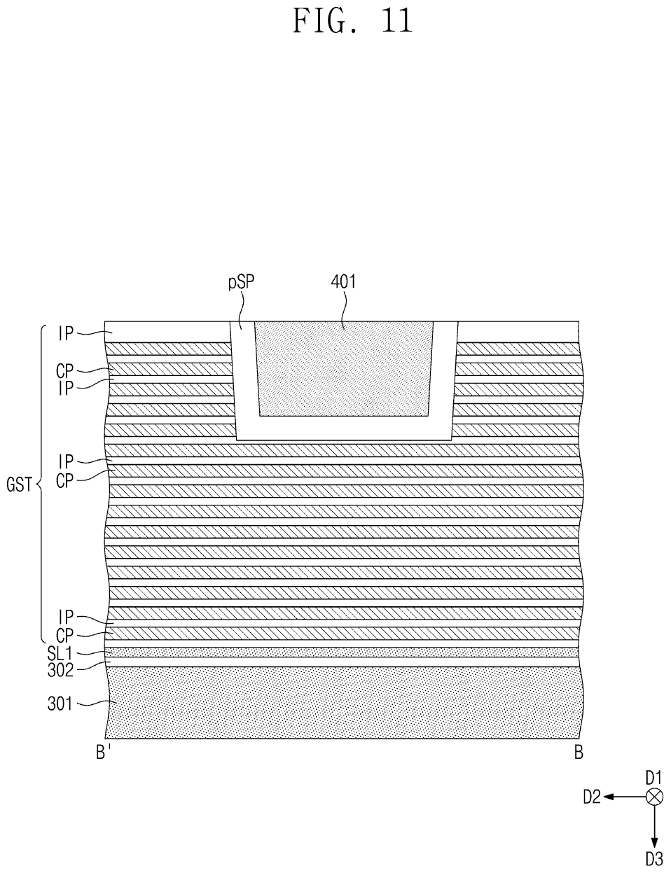

FIGS. 11, 12, 13, 14 and 15 are sectional views illustrating a method of fabricating a semiconductor device, according to an embodiment of the inventive concept. FIGS. 11, 12, 13, 14 and 15 may correspond to FIG. 10C.

Referring to FIG. 11, the preliminary substrate 301, the source sacrificial layer 302, the stack STA, the preliminary spacers pSP, and the contact sacrificial layers 401 may be formed, similar to that described with reference to FIG. 4B.

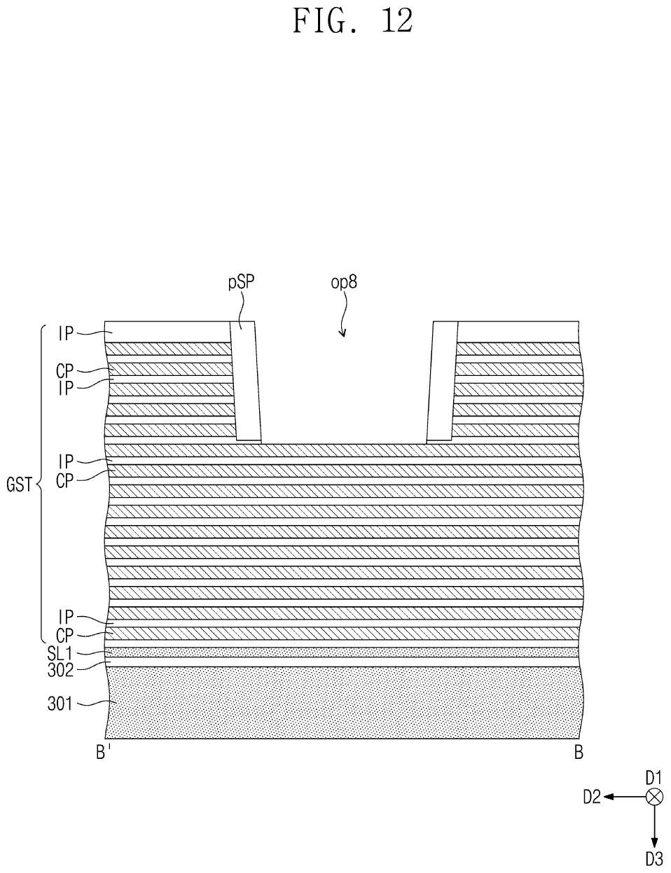

Referring to FIG. 12, an eighth hole op8 may be formed. A portion of the insulating pattern IP, a portion of the preliminary spacer pSP, and the contact sacrificial layer 401 may be removed. An empty space, which is formed by removing the portion of the insulating pattern IP, the portion of the preliminary spacer pSP, and the contact sacrificial layer 401, may be defined as the eighth hole op8. The preliminary spacer pSP and the conductive pattern CP may be exposed through the eighth hole op8.

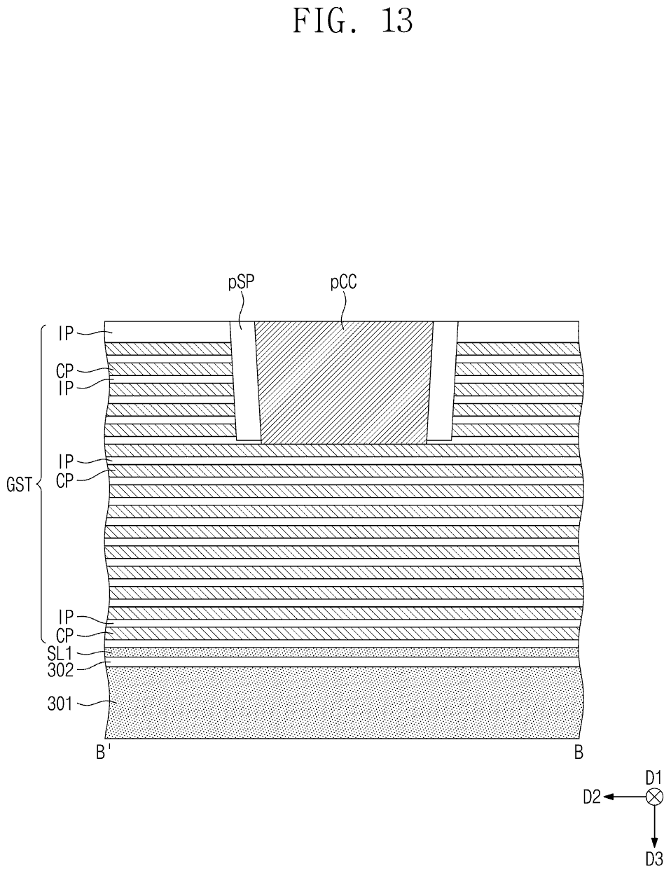

Referring to FIG. 13, preliminary contact plugs pCC may be formed. The preliminary contact plug pCC may be formed by filling the eighth hole op8 with a conductive material. The preliminary contact plug pCC may cover the preliminary spacer pSP and the conductive pattern CP exposed through the eighth hole op8.

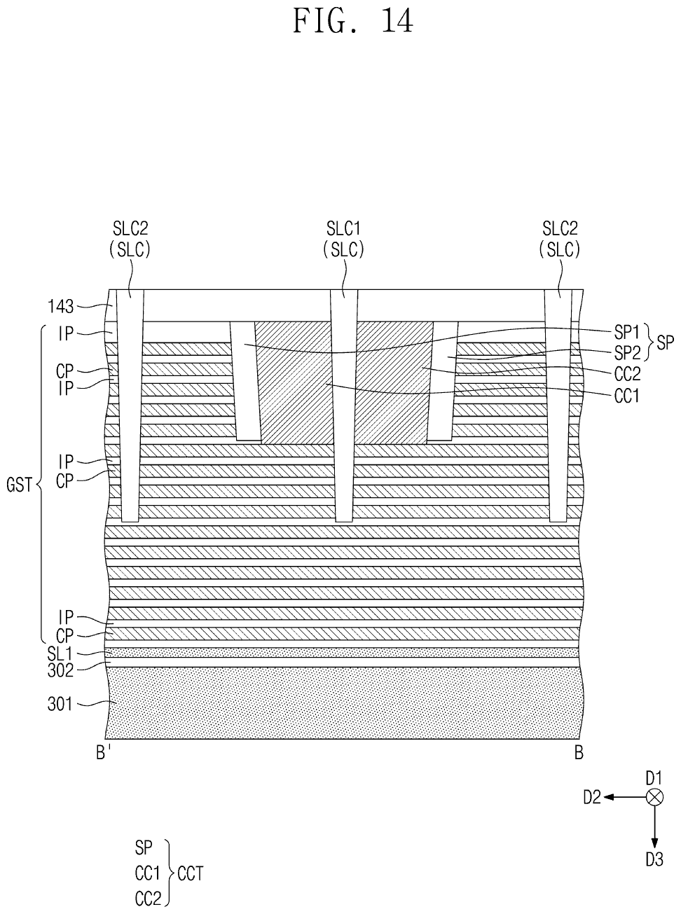

Referring to FIG. 14, the fifth interlayer insulating layer 143 may be formed. The fifth interlayer insulating layer 143 may cover the gate stack GST, the preliminary spacers pSP, and the preliminary contact plugs pCC.

The cutting structure SLC may be formed. The conductive patterns CP, the insulating patterns IP, the preliminary spacers pSP, the preliminary contact plugs pCC, and the fifth interlayer insulating layer 143 may be partially removed. The first cutting pattern SLC1 of the cutting structure SLC may be formed by filling an empty space, which is formed by partially removing the conductive patterns CP, the insulating patterns IP, the preliminary spacer pSP, the preliminary contact plug pCC, and the fifth interlayer insulating layer 143, with an insulating material.

In an embodiment, the preliminary contact plug pCC may include an empty space (e.g., a void) therein. In another embodiment, when the cutting structure SLC is formed, the empty space (e.g., a void) of the preliminary contact plug pCC may be filled with an insulating material.

The first spacers SP1, the second spacers SP2, the first contact plugs CC1, and the second contact plugs CC2 may be formed. As a result of the partial removal of the preliminary spacer pSP, the preliminary spacer pSP may be divided into the first and second spacers SP1 and SP2. A remaining portion of the preliminary spacer pSP, which is left after the partial removal, may be defined as the spacer SP. As a result of the partial removal of the preliminary contact plug pCC, the preliminary contact plug pCC may be divided into the first and second contact plugs CC1 and CC2. The first spacer SP1, the second spacer SP2, the first contact plug CC1, and the second contact plug CC2 may constitute the contact structure CCT.

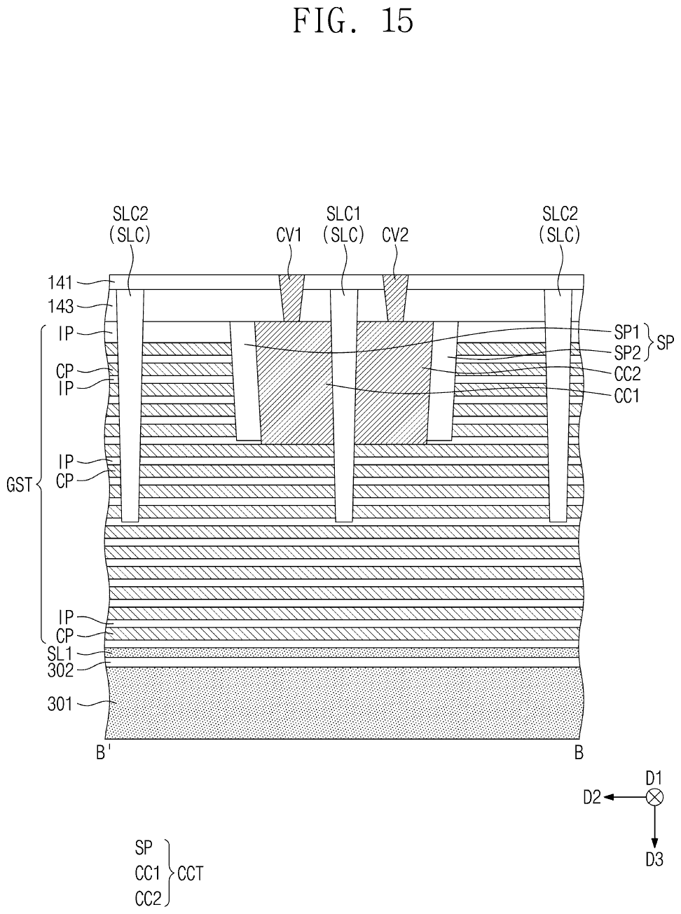

Referring to FIG. 15, the fourth interlayer insulating layer 141 may be formed. The fourth interlayer insulating layer 141 may cover the cutting structure SLC and the fifth interlayer insulating layer 143.

The first contact vias CV1 and the second contact vias CV2 may be formed. For example, the fourth and fifth interlayer insulating layers 141 and 143 may be partially removed. The first and second contact vias CV1 and CV2 may be formed by filling empty spaces, which are formed by partially removing the fourth and fifth interlayer insulating layers 141 and 143, with a conductive material.

Referring back to FIGS. 10A to 10C, the peripheral circuit structure PST, the interconnection structure LST, the source structure SST, the cover insulating layer 210, and the upper vias BV may be formed to have features similar to those described with reference to FIGS. 2A to 2H.

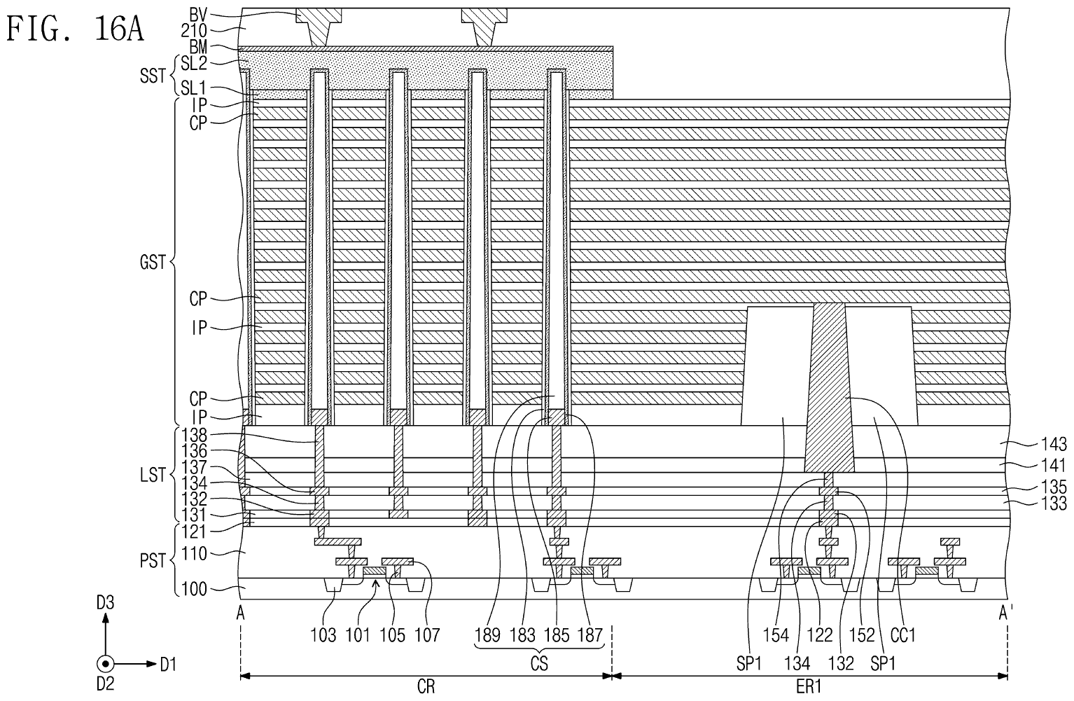

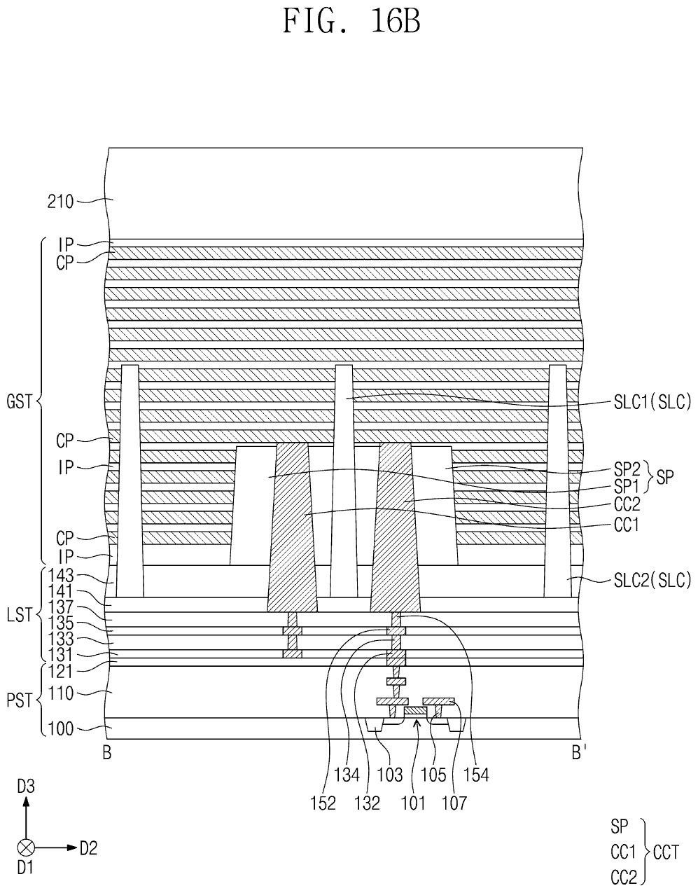

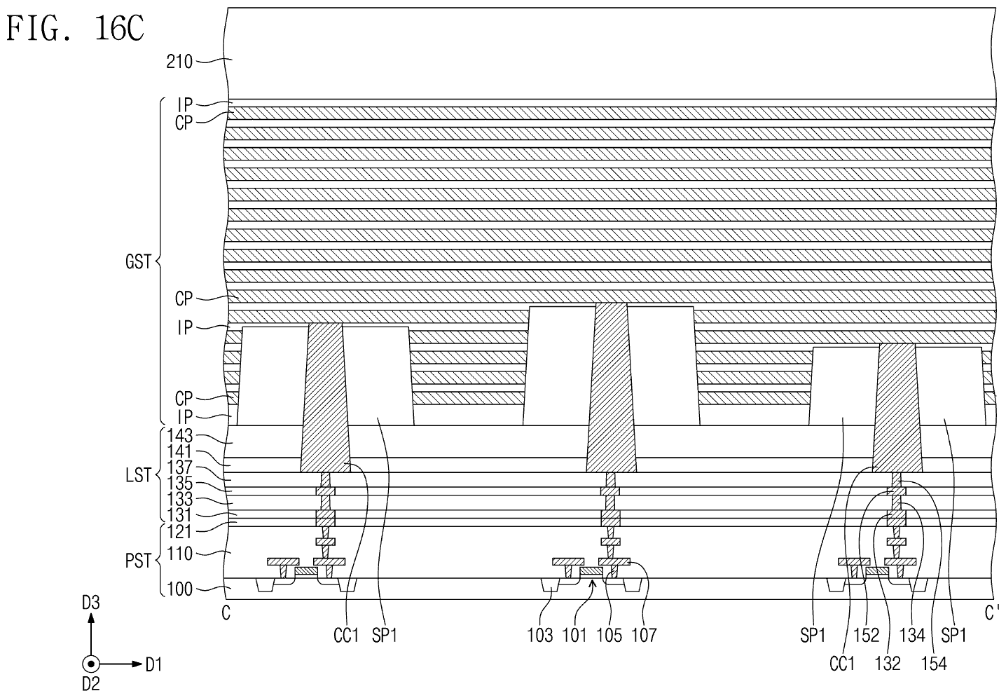

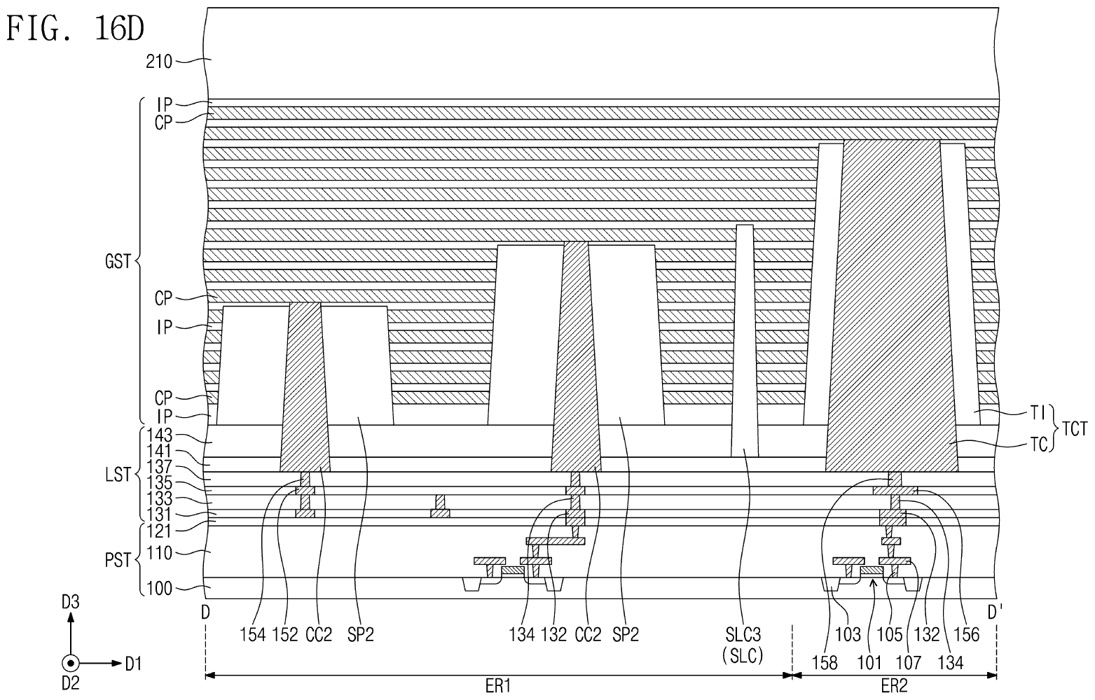

FIGS. 16A, 16B, 16C, and 16D are sectional views illustrating an semiconductor device according to an embodiment of the inventive concept. FIG. 16A may correspond to FIG. 2B. FIG. 16B may correspond to FIG. 2C. FIG. 16C may correspond to FIG. 2D. FIG. 16D may correspond to FIG. 2E. Except for technical features to be described below, the semiconductor device of FIGS. 16A to 16D may be similar to the semiconductor device described with reference to FIGS. 2A to 2H.

Referring to FIGS. 16A to 16D, the semiconductor device may or may not include the inner pattern ISP. The first and second contact plugs CC1 and CC2 may be spaced apart from the first cutting pattern SLC1 of the cutting structure SLC. The first spacer SP1 may be interposed between the first contact plug CC1 and the first cutting pattern SLC1 of the cutting structure SLC. The second spacer SP2 may be interposed between the second contact plug CC2 and the first cutting pattern SLC1 of the cutting structure SLC.

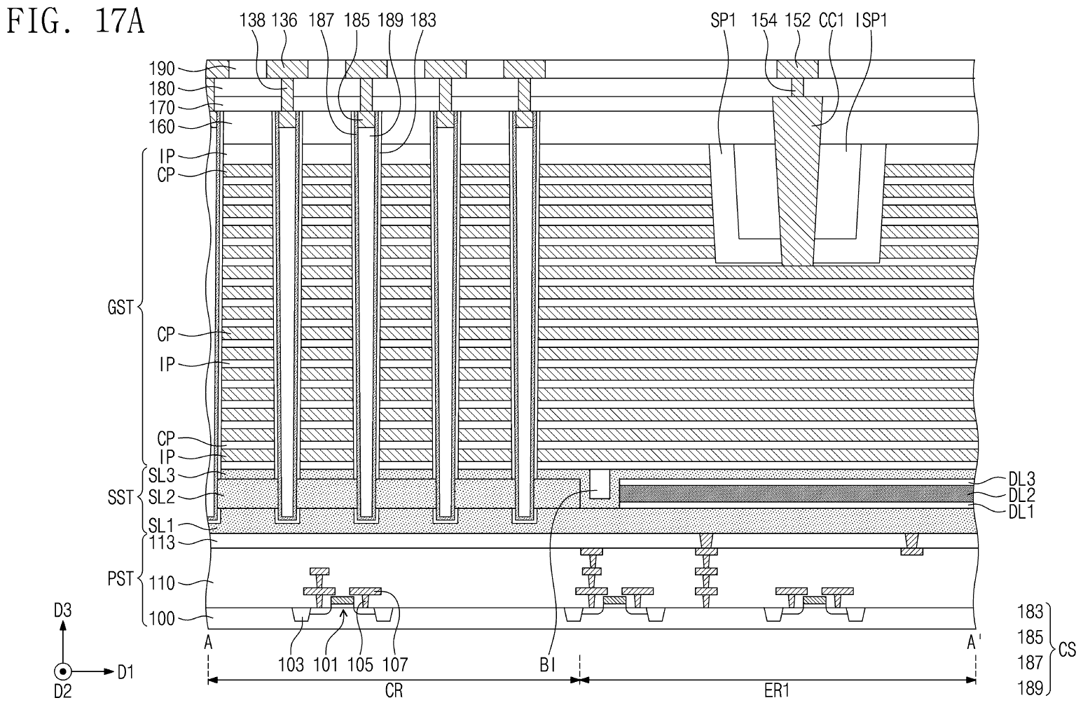

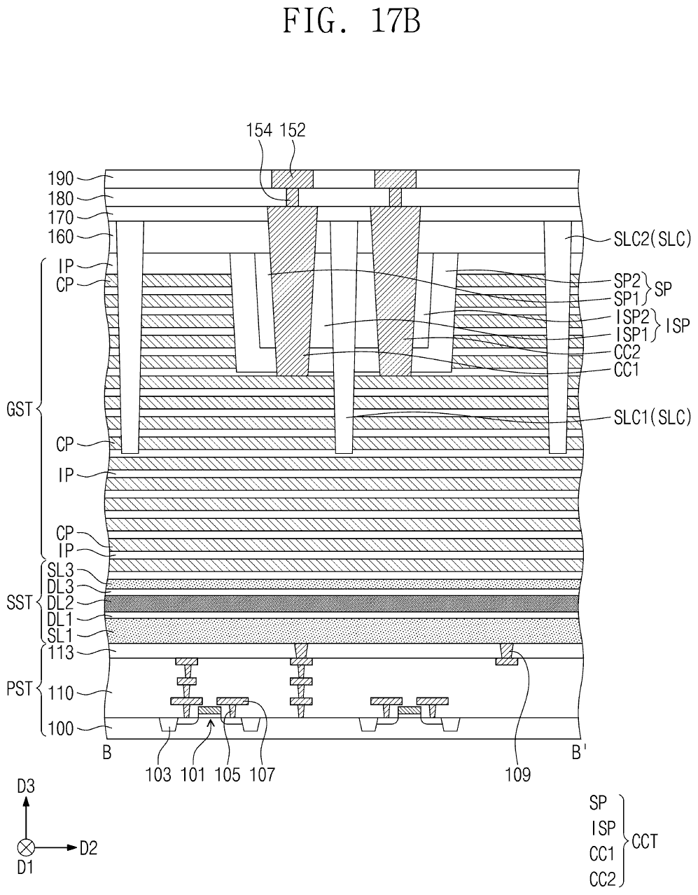

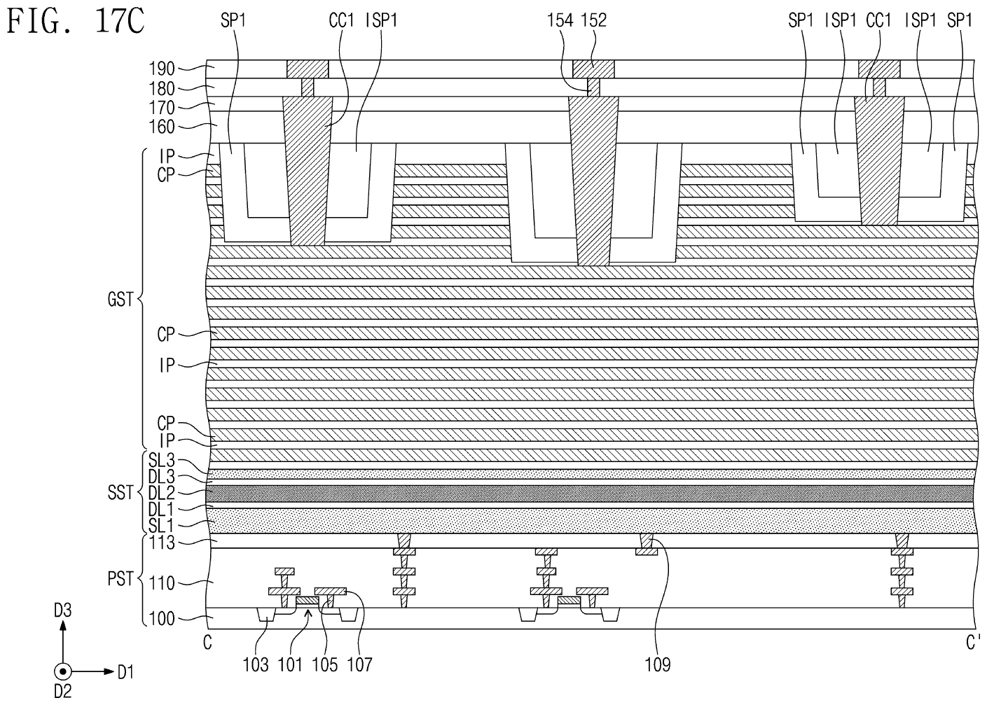

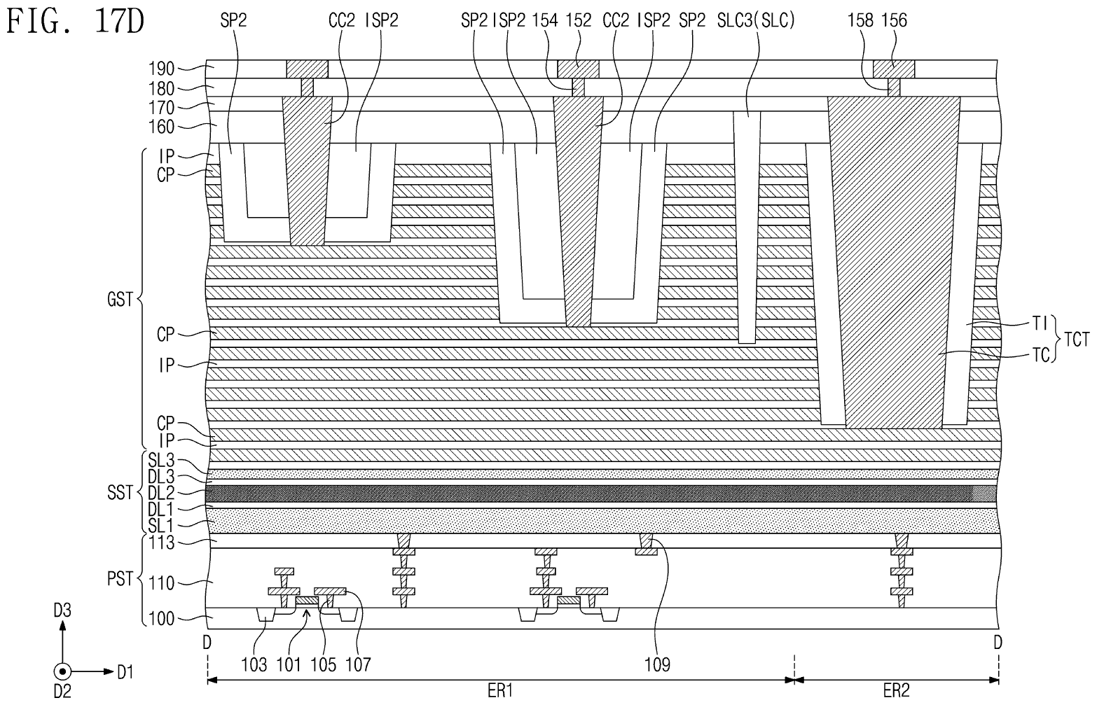

FIGS. 17A, 17B, 17C, and 17D are a sectional view illustrating a semiconductor device according to an embodiment of the inventive concept. FIG. 17A may correspond to FIG. 2B. FIG. 17B may correspond to FIG. 2C. FIG. 17C may correspond to FIG. 2D. FIG. 17D may correspond to FIG. 2E. Except for technical features to be described below, the semiconductor device of FIGS. 17A to 17D may be similar to the semiconductor device described with reference to FIGS. 2A to 2H.

Referring to FIGS. 17A to 17D, the source structure SST may be disposed between the peripheral circuit structure PST and the gate stack GST. The source structure SST may include the first source layer SL1 on the peripheral circuit structure PST, the second source layer SL2 on the first source layer SL1, a first dummy layer DL1, a second dummy layer DL2, and a third dummy layer DL3 on the first source layer SL1, and a third source layer SL3 on the second source layer SL2 and first to third dummy layers DL1, DL2, and DL3.

The first to third source layers SL1, SL2, and SL3 may include a conductive material. In an embodiment, the first to third source layers SL1, SL2, and SL3 may include poly silicon. The second source layer SL2 may be disposed on the cell region CR. The second source layer SL2 may be a common source line.

The first dummy layer DL1, the second dummy layer DL2, and the third dummy layer DL3 may be sequentially provided on the first source layer SL1 in the third direction D3. The first to third dummy layers DL1, DL2, and DL3 may be disposed on an extension region ER1, ER2. The first to third dummy layers DL1, DL2, and DL3 may be disposed at the same level as the second source layer SL2 according to FIGS. 17A to 17D. The first to third dummy layers DL1, DL2, and DL3 may include an insulating material. In an embodiment, the first and third dummy layers DL1 and DL3 may include the same insulating material, and the second dummy layer DL2 may include an insulating material different from the first and third dummy layers DL1 and DL3. As an example, the second dummy layer DL2 may include a nitride material, and the first and third dummy layers DL1 and DL3 may include an oxide material.

The third source layer SL3 may cover the second source layer SL2 and the first to third dummy layers DL1, DL2, and DL3. The third source layer SL3 may be extended from the cell region CR to the extension region ER.

In an embodiment, the source structure SST may further include an insulating gapfill layer BI on the third source layer SL3. The insulating gapfill layer BI may be provided between the cell region CR and the extension region ER. The insulating gapfill layer BI may be provided between the second source layer SL2 and the first to third dummy layers DL1, DL2, and DL3. The second source layer SL2 and the first to third dummy layers DL1, DL2, and DL3 may be spaced apart from each other in the second direction D2, and the insulating gapfill layer BI and a portion of the third source layer SL3 enclosing the insulating gapfill layer BI may be provided between the second source layer SL2 and the first to third dummy layers DL1, DL2, and DL3. The insulating gapfill layer BI may include an insulating material.

The peripheral circuit structure PST may include a peripheral circuit insulating layer 113, instead of the first bonding insulating layer 121 of FIG. 2B to 2F. The peripheral circuit insulating layer 113 may be provided on the peripheral circuit insulating structure 110. The source structure SST may be provided on the peripheral circuit insulating layer 113. The peripheral circuit insulating layer 113 may include an insulating material.

The peripheral circuit structure PST may further include a source connection contact 109. The source connection contact 109 may be connected to the peripheral conductive line 107 and the first source layer SL1. The source connection contact 109 may be provided to penetrate the peripheral circuit insulating layer 113 of the peripheral circuit insulating structure 110. The source connection contact 109 may include a conductive material. As an example, the source connection contact 109 may include poly silicon.

The gate stack GST may be provided on a top surface of the third source layer SL3 of the source structure SST. The cutting structure SLC, the contact structure CCT, and the penetration structure TCT may be enclosed by an upper portion of the gate stack GST. Each of the contact and penetration structures CCT and TCT may be provided to penetrate the upper portion of the gate stack GST and may be connected to the conductive pattern CP of the gate stack GST. In other words, the contact and penetration structures CCT and TCT of FIG. 17A to 17D may have an inverted shape of the contact and penetration structures CCT and TCT of FIG. 2B to 2F.

The memory channel structures CS may be provided to penetrate the gate stack GST, the third source layer SL3, and the second source layer SL2.

A first upper insulating layer 160, a second upper insulating layer 170 on the first upper insulating layer 160, a third upper insulating layer 180 on the second upper insulating layer 170, and a fourth upper insulating layer 190 on the third upper insulating layer 180 may be provided. The first upper insulating layer 160 may be provided on the gate stack GST, the spacer SP, and the inner pattern ISP. The cutting structure SLC may be provided to penetrate the first upper insulating layer 160. The first and second contact plugs CC1 and CC2 may be provided to penetrate the first upper insulating layer 160 and the second upper insulating layer 170.

The bit line contacts 138 may be provided in the second and third upper insulating layers 170 and 180. The first connection contacts 154 and the second connection contacts 158 may be provided in the third upper insulating layer 180. The bit lines 136, the first connection pads 152, and the second connection pads 156 may be provided in the fourth upper insulating layer 190.

The bit line contact 138 may be provided on the bit line pad 185 of the memory channel structure CS. The bit line 136 may be provided on the bit line contact 138. The first connection contact 154 may be provided on a top surface of the first contact plug CC1. The first connection pad 152 may be provided on the first connection contact 154. The second connection contact 158 may be provided on a top surface of the second contact plug CC2. The second connection pad 156 may be provided on the second connection contact 158.

The upper insulating layers 160, 170, 180, and 190 may include an insulating material. In an embodiment, each of the upper insulating layers 160, 170, 180, and 190 may have a multi-layered structure including a plurality of insulating layers.

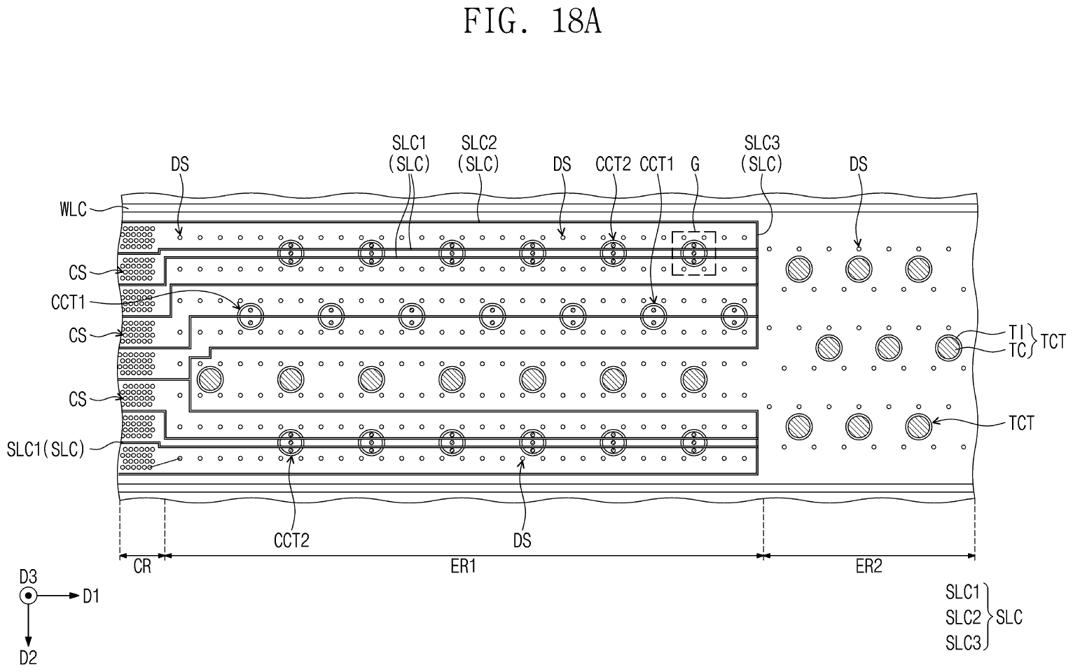

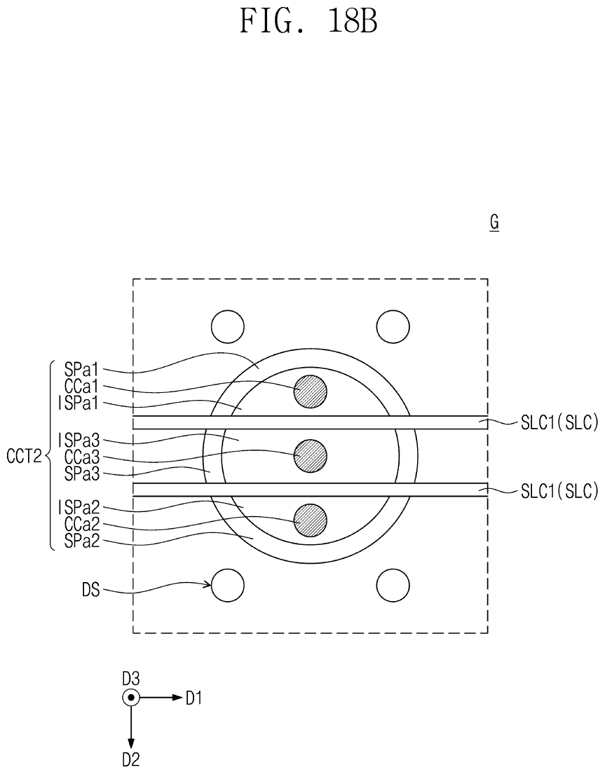

FIG. 18A is a plan view illustrating a semiconductor device according to an embodiment of the inventive concept. FIG. 18B is an enlarged plan view illustrating a portion ‘G’ of FIG. 18A. Except for technical features to be described below, the semiconductor device of FIGS. 18A and 18B may be similar to the semiconductor device described with reference to FIGS. 2A to 2H.

Referring to FIGS. 18A and 18B, may include the semiconductor device may include the penetration structures TCT, first contact structures CCT1, and second contact structures CCT2. The penetration structure TCT and the first contact structure CCT1 of FIG. 18A may be similar to the penetration structure TCT and the contact structure CCT, respectively, of FIGS. 2A to 2H.

The penetration structure TCT may be provided on the first extension region ER1 and the second extension region ER2. The penetration structure TCT on the first extension region ER1 may be disposed between the second cutting patterns SLC2, which are adjacent to each other in the second direction D2. The penetration structure TCT on the second extension region ER2 may be placed between the separation structures WLC.

The second contact structure CCT2 may be penetrated by a pair of the first cutting patterns SLC1, which are spaced apart from each other in the second direction D2. However, the inventive concept is not limited to this example, and the second contact structure CCT2 may be penetrated by the first cutting patterns SLC1, which are spaced apart from each other in the second direction D2. In an embodiment, the second contact structure CCT2 may be penetrated by three or more first cutting patterns SLC1.

The second contact structure CCT2 may include a first contact plug CCa1, a second contact plug CCa2, a third contact plug CCa3, a first spacer SPa1, a second spacer SPa2, a third spacer SPa3, a first inner pattern ISPa1, a second inner pattern ISPa2, and a third inner pattern ISPa3. The first contact plug CCa1, the second contact plug CCa2, the first spacer SPa1, the second spacer SPa2, the first inner pattern ISPa1, and the second inner pattern ISPa2 of the second contact structure CCT2 may be similar to the first contact plug CC1, the second contact plug CC2, the first spacer SP1, the second spacer SP2, the first and second inner patterns ISP1 and ISP2, of FIGS. 2A to 2H.

The third contact plug CCa3 may be disposed between the first contact plug CCa1 and the second contact plug CCa2. The third inner pattern ISPa3 may enclose the third contact plug CCa3. The third contact plug CCa3, the third inner pattern ISPa3, and the third spacer SPa3 may be disposed between a pair of the first cutting patterns SLC1, which are adjacent to each other in the second direction D2. The third inner pattern ISPa3 and the third spacer SPa3 may be in contact with the pair of the first cutting patterns SLC1, which are adjacent to each other in the second direction D2.

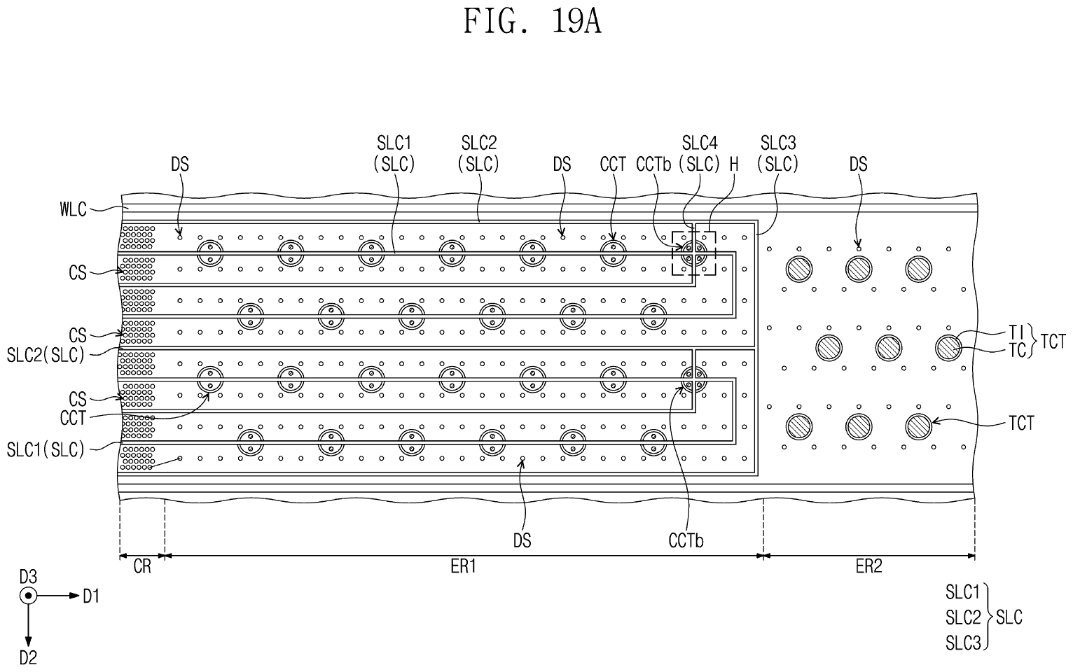

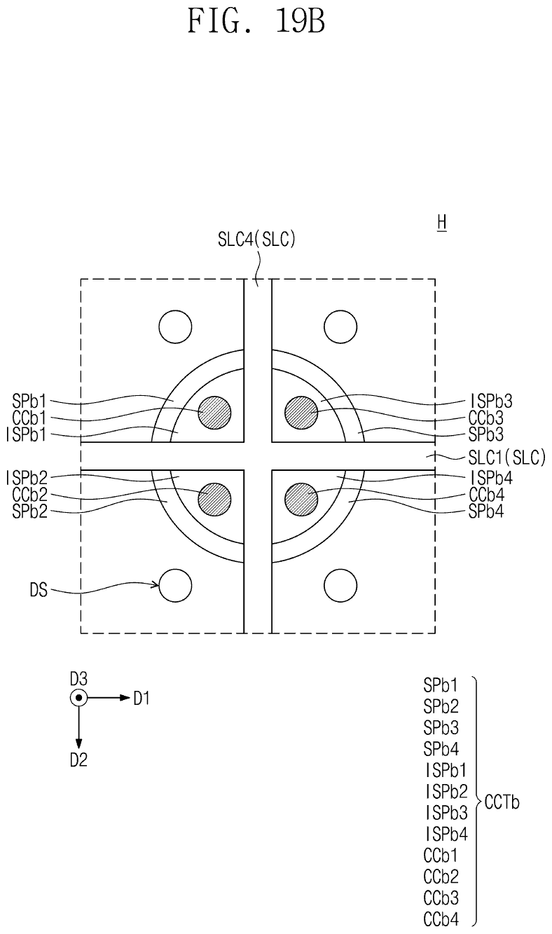

FIG. 19A is a plan view illustrating a semiconductor device according to an embodiment of the inventive concept. FIG. 19B is an enlarged plan view illustrating a portion ‘H’ of FIG. 19A. Except for technical features to be described below, the semiconductor device of FIGS. 19A and 19B may be similar to the semiconductor device described with reference to FIGS. 2A to 2H.

Referring to FIGS. 19A and 19B, the semiconductor device may include the contact structures CCT and separation contact structures CCTb. The contact structure CCT of FIG. 19A may be similar to the contact structure CCT of FIGS. 2A to 2H.

The cutting structure SLC may further include the first cutting pattern SLC1, the second cutting pattern SLC2, the third cutting pattern SLC3, and a fourth cutting pattern SLC4. The first, second, and third cutting patterns SLC1, SLC2, and SLC3 of FIGS. 19A and 19B may be similar to the first, second, and third cutting patterns SLC1, SLC2, and SLC3 of FIGS. 2A to 2H. The fourth cutting pattern SLC4 may be extended in the second direction D2. The fourth cutting pattern SLC4 may be spaced apart from the third cutting pattern SLC3. The fourth cutting pattern SLC4 may be parallel to the third cutting pattern SLC3. The fourth cutting pattern SLC4 may be connected to the first cutting pattern SLC1 and the second cutting pattern SLC2. The fourth cutting pattern SLC4 may be in contact with the separation contact structure CCTb.

The separation contact structure CCTb may be penetrated by the first and fourth cutting patterns SLC1 and SLC4. The separation contact structure CCTb may include a first separation contact plug CCb1, a second separation contact plug CCb2, a third separation contact plug CCb3, a fourth separation contact plug CCb4, a first separation spacer SPb1, a second separation spacer SPb2, a third separation spacer SPb3, a fourth separation spacer SPb4, a first separation inner pattern ISPb1, a second separation inner pattern ISPb2, a third separation inner pattern ISPb3, and a fourth separation inner pattern ISPb4.

The first separation inner pattern ISPb1 may enclose the first separation contact plug CCb1. The second separation inner pattern ISPb2 may enclose the second separation contact plug CCb2. The third separation inner pattern ISPb3 may enclose the third separation contact plug CCb3. The fourth separation inner pattern ISPb4 may enclose the fourth separation contact plug CCb4. The first to fourth separation inner patterns ISPb1, ISPb2, ISPb3, and ISPb4 may be in contact with the first and fourth cutting patterns SLC1 and SLC4.

The first separation inner pattern ISPb1 may be enclosed by the first separation spacer SPb1, the first cutting pattern SLC1, and the fourth cutting pattern SLC4. The second separation inner pattern ISPb2 may be enclosed by the second separation spacer SPb2, the first cutting pattern SLC1, and the fourth cutting pattern SLC4. The third separation inner pattern ISPb3 may be enclosed by the third separation spacer SPb3, the first cutting pattern SLC1, and the fourth cutting pattern SLC4. The fourth separation inner pattern ISPb4 may be enclosed by the fourth separation spacer SPb4, the first cutting pattern SLC1, and the fourth cutting pattern SLC4.

The first and second separation contact plugs CCb1 and CCb2 may be spaced apart from each other, with the first cutting pattern SLC1 interposed therebetween. The first separation contact plug CCb1 and the third separation contact plug CCb3 may be spaced apart from each other, with the fourth cutting pattern SLC4 interposed therebetween. The third separation contact plug CCb3 and the fourth separation contact plug CCb4 may be spaced apart from each other, with the first cutting pattern SLC1 interposed therebetween. The first separation contact plug CCb1 and the third separation contact plug CCb3 may be spaced apart from each other, with the fourth cutting pattern SLC4 interposed therebetween.

In a semiconductor device according to an embodiment of the inventive concept and an electronic system including the same, a cutting pattern may be provided to penetrate a contact structure. In this case, an area of the contact structure may be reduced, and this may make it possible to increase an integration density of the semiconductor device and to improve electrical characteristics of the semiconductor device.

In a method of fabricating of a semiconductor device and an electronic system including the same according to an embodiment of the inventive concept, a spacer and a penetration insulating layer may be formed at the same time. Thus, the fabrication process of the semiconductor device may be simplified.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a gate stack including at least two conductive patterns and at least two insulating patterns, which are alternately stacked on top of each other;
a memory channel structure at least partially penetrating the gate stack;
a contact structure at least partially enclosed by the gate stack;
a penetration structure at least partially enclosed by the gate stack; and
a cutting structure including a first cutting pattern at least partially penetrating the contact structure,
wherein the conductive patterns comprises a first conductive pattern, a second conductive pattern, and a third conductive pattern, wherein the first conductive pattern and the second conductive pattern are coplanar with each other and the second conductive pattern is not coplanar with the third conductive pattern,
wherein the contact structure comprises:
a first contact plug in contact with the first conductive pattern;
a second contact plug in contact with the second conductive pattern; and
a spacer at least partially enclosing the first and second contact plugs,
wherein the cutting structure is spaced apart from the third conductive pattern, and
the first cutting pattern at least partially penetrates the spacer and is between the first and second contact plugs.

2. The semiconductor device of claim 1, wherein the cutting structure further comprises a pair of second cutting patterns, which are adjacent to each other with the first cutting pattern interposed therebetween,
the first contact plug is between one of the second cutting patterns and the first cutting pattern, and
the second contact plug is between the other of the second cutting patterns and the first cutting pattern.

3. The semiconductor device of claim 1, wherein the first cutting pattern is between the first and second contact plugs.

4. The semiconductor device of claim 1, wherein the first cutting pattern is spaced apart from the first and second contact plugs.

5. The semiconductor device of claim 1, wherein the first cutting pattern is in contact with the first and second contact plugs.

6. The semiconductor device of claim 1, wherein the spacer comprises a first spacer, which is overlapped by the first conductive pattern in a direction of penetration of the cutting structure, and a second spacer, which is overlapped by the second conductive pattern in a direction of penetration of the cutting structure,
the first contact plug penetrates the first spacer, and
the second contact plug penetrates the second spacer.

7. The semiconductor device of claim 6, further comprising:
a first inner pattern in contact with the first spacer and the first contact plug; and
a second inner pattern in contact with the second spacer and the second contact plug.

8. The semiconductor device of claim 7, wherein the first cutting pattern is in contact with the first inner pattern and the second inner pattern.

9. The semiconductor device of claim 7, wherein the first inner pattern comprises a material having an etch selectivity with respect to the first spacer.

10. The semiconductor device of claim 7, wherein the first spacer comprises a contact surface in contact with the first inner pattern and an inner side surface in contact with the first inner pattern.

11. The semiconductor device of claim 10, wherein the first cutting pattern comprises a first side surface in contact with the first inner pattern, and
the first contact plug is between the inner side surface of the first spacer and the first side surface of the first cutting pattern.

12. The semiconductor device of claim 10, wherein the contact surface of the first spacer is sufficiently flat, and
a part of the inner side surface of the first spacer is curved.

13. A semiconductor device, comprising:
a gate stack including conductive patterns and insulating patterns, which are alternately stacked on top of each other;
a memory channel structure at least partially penetrating the gate stack;
a contact structure at least partially enclosed by the gate stack;
a penetration structure at least partially enclosed by the gate stack; and
a cutting structure including a cutting pattern at least partially penetrating the contact structure,
wherein the conductive patterns comprises a first conductive pattern, a second conductive pattern, and a third conductive pattern, wherein the first conductive pattern and the second conductive pattern are coplanar with each other and the second conductive pattern is not coplanar with the third conductive pattern,
wherein the contact structure comprises:
a first contact plug in contact with the first conductive pattern;
a second contact plug in contact with the second conductive pattern; and
a spacer enclosing the first and second contact plugs,
wherein the third conductive pattern is at least partially overlapped by the first conductive pattern, the second conductive pattern, and the cutting pattern in a direction parallel to the direction of penetration of the cutting pattern.

14. The semiconductor device of claim 13, wherein the insulating patterns comprises:
a first insulating pattern in contact with the first conductive pattern and the first contact plug; and
a second insulating pattern in contact with the second conductive pattern and the second contact plug.

15. The semiconductor device of claim 14, wherein the spacer comprises a first spacer, which is at least partially overlapped by the first conductive pattern in a direction of penetration of the cutting structure, and a second spacer, which is overlapped with the second conductive pattern in a direction of penetration of the cutting structure,
the first insulating pattern comprises an intervening portion between the first conductive pattern and the first spacer, and
the intervening portion of the first insulating pattern is in contact with the cutting pattern.

16. The semiconductor device of claim 15, further comprising an inner pattern in contact with the first spacer and the cutting pattern,
wherein the first contact plug comprises:
a first side surface in contact with the intervening portion of the first insulating pattern;
a second side surface in contact with the first spacer; and
a third side surface in contact with the cutting pattern.

17. The semiconductor device of claim 13, wherein a distance between the first and second contact plugs decreases as a distance from the third conductive pattern decreases.

18. The semiconductor device of claim 13, wherein the spacer is in contact with the first contact plug, the second contact plug, and the cutting pattern.

19. An electronic system, comprising:
a main substrate;
a semiconductor device on the main substrate; and
a controller arranged on the main substrate and electrically connected to the semiconductor device,
wherein the semiconductor device comprises:
a gate stack including at least two conductive patterns and at least two insulating patterns, which are alternately stacked on top of each other;
a memory channel structure at least partially penetrating the gate stack;
a contact structure at least partially enclosed by the gate stack;
a penetration structure at least partially enclosed by the gate stack; and
a cutting structure including a cutting pattern at least partially penetrating the contact structure,
wherein the conductive patterns comprises a first conductive pattern, a second conductive pattern, and a third conductive pattern, wherein the first conductive pattern and the second conductive pattern are coplanar with each other and the second conductive pattern is not coplanar with the third conductive pattern,
wherein the contact structure comprises:
a first contact plug in contact with the first conductive pattern;
a second contact plug in contact with the second conductive pattern;
a first spacer overlapped by the first conductive pattern in a direction of penetration of the cutting structure; and
a second spacer overlapped by the second conductive pattern in a direction of penetration of the cutting structure,
wherein the cutting structure is spaced apart from the third conductive pattern,
each of the first and second spacers comprises a contact surface in contact with the cutting pattern, and
the contact surface of the first spacer and the contact surface of the second spacer face each other.

20. The electronic system of claim 19, wherein the contact structure further comprises a penetration contact and a penetration insulating layer at least partially enclosing the penetration contact, and
the largest width of the penetration insulating layer is substantially equal to the largest distance between the first spacer and the second spacer.
